(19) United States
(12) Patent Application Publication
(10) Pub. No.: US 2022/0145037 A1
(43) Pub. Date: May 12, 2022

(54) METHODS OF PREPARATION OF OMNIPHOBIC SURFACES

(71) Applicant: NUtech Ventures, Lincoln, NE (US)

(72) Inventors: Siamak Nejati, Lincoln, NE (US); Mona Bavarian, Lincoln, NE (US); Mahdi Mohammadi Ghaleni, Lincoln, NE (US)

(21) Appl. No.: 17/520,611

(22) Filed: Nov. 5, 2021

Related U.S. Application Data
(60) Provisional application No. 63/198,695, filed on Nov. 5, 2020.

(51) Int. Cl. C08J 9/36; C09D 127/18; C09D 133/16; C09D 5/00; B05D 1/00

(52) U.S. Cl. CPC C08J 9/365; C09D 127/18; C09D 133/16; C08J 2433/16; B05D 1/60; C08J 2327/16; C08J 2427/18; C09D 5/002

(57) ABSTRACT

Provided here are compositions and methods for preparing porous omniphobic surfaces with desirable chemical and structural properties. The methods include sequential initiated chemical vapor deposition (iCVD) of low surface-energy materials onto a variety of substrates.

### STATEMENT REGARDING FEDERALLY SPONSORED RESEARCH OR DEVELOPMENT

This invention was made with government support under R17AC00139 awarded by the U.S. Department of the Interior, Bureau of Reclamation, and under ECCS 1542182, awarded by the National Science Foundation. The government has certain rights in the invention.

### TECHNICAL FIELD

The present disclosure relates to methods for the preparation of porous omniphobic surfaces. The methods include sequential initiated chemical vapor deposition (iCVD) of low surface-energy materials onto a variety of substrates.

### BACKGROUND

Surfaces that repel virtually any liquid are referred to as omniphobic. Omniphobic surfaces prevent liquids of a variety of polarities from wetting, or spreading out to cover the surface. Rather, the liquids bead up on the surface as droplets. The utility of such surfaces in a variety of applications has been recognized, such as in carbon dioxide capture, microfluidic devices, water-energy harvesting, chemical shielding, and water treatment. The degree to which a surface repels liquids depends on two critical properties of the surface: surface energy and topography. The surface energy determines the interfacial interactions between the liquid and solid phases, through influencing the intermolecular forces, while surface topography defines the interfacial areas.

Reentrant structures have been deemed necessary for repelling low-surface-tension liquids (i.e., omniphobicity). Reentrant structures have a surface topography which cannot be described by a simple univalued function, and a vector projected normal to the x-y plane intersects the surface more than once. When a liquid droplet is brought into contact with a solid surface bearing reentrant structures, the liquid partially diffuses through the structure. As the liquid penetration proceeds, the wetted area increases. At some point, the Gibbs free energy of the system reaches a minimum value, causing the liquid penetration to cease.

Assembly of reentrant structures on a variety of planar substrates has been widely demonstrated. A variety of approaches, such as lithography or solution-phase self-assembly, have shown promise in creating the desired reentrant structures. Nonetheless, progress with creating reentrant structures on porous substrates and membranes has been limited by the complexity of the proposed schemes. For example, the majority of existing methods for the fabrication of omniphobic domains on membrane surfaces are multi-step and time-consuming, making them very challenging to scale up. Additionally, to achieve the desired surface topographies, in most of the reported approaches, nanoparticles and nanomaterials have been employed. The potential health and environmental hazards of using these particles make the large scale application of the proposed methods less attractive. Accordingly, there is a need to provide methods of preparing porous substrates and membranes having an omniphobic surface that are scalable and more environmentally sustainable.

### SUMMARY

Provided herein are scalable, bottom-up methods for rendering a porous matrix omniphobic. One such method utilizes a sequential initiated chemical vapor deposition (iCVD) of fluoropolymers to impart the desired chemical and structural properties to hydrophobic porous substrates. Surprisingly, according to the present disclosure, by adjusting the rate of radical polymerization and controlling the growth mechanism in the iCVD process, reentrant structures are assembled on polymeric membrane surfaces, rendering the surfaces super-hydrophobic. Subsequently, depositing a thin film of low surface-energy material on the reentrant structures extended the non-wetting properties of the membrane to a range of liquids of different polarities. The disclosed methods allow for the fabrication of omniphobic membranes with sub-10 nanometers (nm) precision, and having desirable physical properties, through scalable and continuous processes.

Embodiments include methods for preparing a material having an omniphobic porous surface. One such method includes the steps of providing a porous substrate and adjusting the average pore size and porosity of the porous substrate through controlled deposition of a first layer, wherein the controlled deposition includes performing initiated chemical vapor deposition (iCVD) under reaction-limited conditions with a first monomer in the presence of a first initiator at a first substrate temperature, a first filament temperature, a first pressure, and a first monomer to initiator ratio, and wherein the first layer is a conformal coating. The method further includes a step of assembling a reentrant structure on the porous substrate through controlled deposition of a second layer, wherein the controlled deposition comprises performing iCVD under diffusion-limited conditions with a second monomer in the presence of a second initiator at a second substrate temperature, a second filament temperature, a second pressure, and a second monomer to initiator ratio, and wherein the second layer is a non-conformal coating. The method further includes a step of engineering the surface energy of the reentrant structure that includes grafting a third layer onto the second layer. This grafting step includes performing iCVD under reaction-limited conditions with a third monomer in the presence of a third initiator at a third substrate temperature, a third filament temperature, a third pressure, and a third monomer to initiator ratio. In certain embodiments, the third layer is a conformal coating.

In some embodiments, the porous substrate contains poly(vinylidene fluoride) (PVDF), polytetrafluoroethylene (Teflon), polyester, nylon, polycarbonate, cellulose acetate, polysulfone, ceramic, carbon nanotubes, titania nanowire, or any combination thereof.

In some embodiments, the first pressure is from about 100 millitorr (mTorr) to about 3 Torr. In some embodiments, the first pressure is from about 100 mTorr to about 1200 mTorr, about 100 mTorr to about 600 mTorr, or from about 200 mTorr to about 400 mTorr. In some embodiments, the first filament temperature is from about 200 to about 500° C., or from about 300 to about 400° C. In some embodiments, the first substrate temperature is from about 0° C. to about 100° C., from about 10° C. to about 50° C., or from about 10° C. to about 20° C. In some embodiments, the adjusted pore size is from about 100 nanometers (nm) to about 100 micrometers (μall), from about 100 nm to about 1 μm, or from about 300 to about 500 nm. In some embodiments, the porous substrate is a membrane, a felt, a fabric, or a filter. In some embodiments, the porous substrate contains PVDF. In some embodiments, the PVDF is hydrophilic. In some embodiments, the porous substrate is a membrane made of nylon, polycarbonate, ceramic, or combinations thereof. In some embodiments, the porous substrate is one or more of PVDF, hydrophilic PVDF, polytetrafluoroethylene, polyester fabric, nylon membrane, cellulose acetate, polycarbonate membrane, a ceramic membrane, an electrospun fiber mat of PVDF, a polysulfone, a carbon nanotube felt, and a titania nanowire filter.

In some embodiments, the first monomer is one or more of hexafluoropropylene oxide, perfluorodecyl acrylate, glycidyl methacrylate, 1,3,5,7-tetravinyl-1,3,5,7-tetramethylcyclotetrasiloxane, 1,3,5-trimethyl-1,3,5-trivinyl cyclotrisiloxane, diethylaminoethyl methacrylate, 2,2,3,3-tetrafluoropropyl methacrylate, 2,2,3,3,4,4,5,5-Octafluoropentyl methacrylate, 2,2,3,3,4,4,4-heptafluorobutyl acrylate, 2,2,3,4,4,4-Hexafluorobutyl acrylate, 2,2,3,3-Tetrafluoropropyl methacrylate, 1H, 1H-perfluorooctyl methacrylate, 3,3,4,4,5,5,6,6,7,7,8,8,8-tridecafluorooctyl acrylate, 3,3,4,4,5,5,6,6,7,7,8,8,9,9,10,10,11,11,12,12,12-heneicosafluorododecyl acrylate, 2,2,2-trifluoroethyl acrylate, 1,1,1,3,3,3-hexafluoroisopropyl acrylate, 2,2,3,3,4,4,4-Heptafluorobutyl acrylate, or pentafluorophenyl methacrylate. In some embodiments, the first monomer is hexafluoropropylene oxide.

In some embodiments, the first layer contains one or more of polytetrafluoroethylene, poly(perfluorodecyl acrylate), poly(glycidyl methacrylate), poly(1,3,5,7-tetravinyl-1,3,5,7-tetramethylcyclotetrasiloxane), poly(1,3,5-trimethyl-1,3,5-trivinyl cyclotrisiloxane), poly (diethylaminoethyl methacrylate), poly(2,2,3,3-tetrafluoropropyl methacrylate), poly(2,2,3,3,4,4,5,5-octafluoropentylmethacrylate), poly(2,2,3,3,4,4,4-heptafluorobutyl acrylate), poly(2,2,3,4,4,4-hexafluorobutyl acrylate), poly(2,2,3,3-tetrafluoropropyl methacrylate), poly(1h,1h-perfluorooctyl methacrylate), poly(3,3,4,4,5,5,6,6,7,7,8,8,8-tridecafluorooctyl acrylate), poly(3,3,4,4,5,5,6,6,7,7,8,8,9,9,10,10,11,11,12,12,12-heneicosafluorododecyl acrylate), poly(2,2,2-trifluoroethyl acrylate), poly(1,1,1,3,3,3-hexafluoroisopropyl acrylate), poly(2,2,3,3,4,4,4-heptafluorobutyl acrylate), or poly(pentafluorophenyl methacrylate). In some embodiments, the first layer is polytetrafluoroethylene.

In some embodiments, the first initiator is a peroxide or a sulfonyl fluoride. In some embodiments, the first initiator is tert-butyl peroxide, tert-amyl peroxide, or perfluoro-1-butanesulfonyl fluoride. In some embodiments, the second monomer is one or more of hexafluoropropylene oxide, perfluorodecyl acrylate, glycidyl methacrylate, 1,3,5,7-tetravinyl-1,3,5,7-tetramethylcyclotetrasiloxane, 1,3,5-trimethyl-1,3,5-trivinyl cyclotrisiloxane, diethylaminoethyl methacrylate, 2,2,3,3-tetrafluoropropyl methacrylate, 2,2,3,3,4,4,5,5-Octafluoropentyl methacrylate, 2,2,3,3,4,4,4-heptafluorobutyl acrylate, 2,2,3,4,4,4-Hexafluorobutyl acrylate, 2,2,3,3-tetrafluoropropyl methacrylate, 1H,1H-perfluorooctyl methacrylate, 3,3,4,4,5,5,6,6,7,7,8,8,8-tridecafluorooctyl acrylate, 3,3,4,4,5,5,6,6,7,7,8,8,9,9,10,10,11,11,12,12,12-heneicosafluorododecyl acrylate, 2,2,2-trifluoroethyl acrylate, 1,1,1,3,3,3-hexafluoroisopropyl acrylate, 2,2,3,3,4,4,4-heptafluorobutyl acrylate, and pentafluorophenyl methacrylate. In some embodiments, the second monomer is hexafluoropropylene oxide.

In some embodiments, the second layer contains one or more of polytetrafluoroethylene, poly(perfluorodecyl acrylate), poly(glycidyl methacrylate), poly(1,3,5,7-tetravinyl-1,3,5,7-tetramethylcyclotetrasiloxane), poly(1,3,5-trimethyl-1,3,5-trivinyl cyclotrisiloxane), poly (diethylaminoethyl methacrylate), poly(2,2,3,3-tetrafluoropropyl methacrylate), poly(2,2,3,3,4,4,5,5-octafluoropentylmethacrylate), poly(2,2,3,3,4,4,4-heptafluorobutyl acrylate), poly(2,2,3,4,4,4-hexafluorobutyl acrylate), poly(2,2,3,3-tetrafluoropropyl methacrylate), poly(1h,1h-perfluorooctyl methacrylate), poly(3,3,4,4,5,5,6,6,7,7,8,8,8-tridecafluorooctyl acrylate), poly(3,3,4,4,5,5,6,6,7,7,8,8,9,9,10,10,11,11,12,12,12-heneicosafluorododecyl acrylate), poly(2,2,2-trifluoroethyl acrylate), poly(1,1,1,3,3,3-hexafluoroisopropyl acrylate), poly(2,2,3,3,4,4,4-heptafluorobutyl acrylate), or poly(pentafluorophenyl methacrylate). In some embodiments, the second layer is polytetrafluoroethylene.

In some embodiments, the second initiator is a peroxide or a sulfonyl fluoride. In some embodiments, the second initiator is tert-butyl peroxide, tert-amyl peroxide, or perfluoro-1-butanesulfonyl fluoride.

In some embodiments, the third monomer is one or more of perfluorodecyl acrylate (PFDA), 1,3,5,7-tetravinyl-1,3,5,7-tetramethylcyclotetrasiloxane, 1,3,5-trimethyl-1,3,5-trivinyl cyclotrisiloxane, 2,2,3,3,4,4,4-heptafluorobutyl methacrylate, 3,3,4,4,5,5,6,6,7,7,8,8,8-tridecafluorooctyl methacrylate, 2,2,3,3-tetrafluoropropyl methacrylate, 2,2,3,3,4,4,5,5-octafluoropentyl methacrylate, 2,2,3,3,4,4,4-heptafluorobutyl acrylate, 2,2,3,4,4,4-hexafluorobutyl acrylate, or 2,2,3,3-tetrafluoropropyl methacrylate.

In some embodiments, the third layer contains one or more of poly(perfluorodecyl acrylate) (PPFDA), poly(1,3,5,7-tetravinyl-1,3,5,7-tetramethylcyclotetrasiloxane), poly(1,3,5-trimethyl-1,3,5-trivinyl cyclotrisiloxane), poly(2,2,3,3,4,4,4-heptafluorobutyl methacrylate), poly(3,3,4,4,5,5,6,6,7,7,8,8,8-tridecafluorooctyl methacrylate), poly(2,2,3,3-tetrafluoropropyl methacrylate), poly(2,2,3,3,4,4,5,5-octafluoropentyl methacrylate), poly(2,2,3,3,4,4,4-heptafluorobutyl acrylate), poly(2,2,3,4,4,4-hexafluorobutyl acrylate), or poly(2,2,3,3-tetrafluoropropyl methacrylate). In some embodiments, the third layer is PPFDA

In some embodiments, the third initiator is a peroxide or a sulfonyl fluoride. In some embodiments, the third initiator is tert-butyl peroxide, tert-amyl peroxide, or perfluoro-1-butanesulfonyl fluoride.

In some embodiments, the second pressure is from about 600 mTorr to about 3 Torr. In some embodiments, the second pressure is from about 600 mTorr to about 1200 mTorr. In some embodiments, the second filament temperature is from about 200° C. to about 500° C., or from about 300° C. to about 400° C. In some embodiments, the second substrate temperature is from about 0° C. to about 100° C., from about 10° C. to about 50° C., or from about 10° C. to about 20° C.

In some embodiments, the third pressure is from about 100 mTorr to about 3 Torr. In some embodiments, the third pressure is from about 100 mTorr to about 600 mTorr, or from about 200 mTorr to about 400 mTorr. In some embodiments, the third filament temperature is from about 200° C. to about 500° C., or from about 300° C. to about 400° C. In some embodiments, the third substrate temperature is from about 0° C. to about 100° C., from about 10° C. to about 50° C., or from about 10° C. to about 20° C.

In some embodiments, the method further includes adjusting a monomer to initiator flow rate between 0 and about 15. In some embodiments, a ratio of the first monomer to the first initiator is from about 0.1 to about 100, or from about 3 to about 12. In some embodiments, a ratio of the second monomer to the second initiator is from about 0.1 to about 100, or about 3 to about 12. In some embodiments, a ratio of the third monomer to the third initiator is from about 0.1 to about 100, or about 3 to about 12.

In some embodiments, each of the controlled deposition and the grafting is performed for a period of time independently selected for each occasion. The period of time varies from about 1 minute to about 60 minutes. In some embodiments, the method is performed as a continuous process. In some embodiments, the omniphobic porous surface is resistant against wetting by impacting liquids with Weber numbers between 100 and 500. In some embodiments, droplets of deionized water, ethylene glycol, canola oil, hexadecane, and ethanol form a contact angle between 80 and 175 degrees on the omniphobic porous surface.

These and other features, aspects, and advantages of the disclosure will be apparent from the following detailed description together with the accompanying drawings, which are briefly described below.

### BRIEF DESCRIPTION OF THE DRAWINGS

In order to provide an understanding of embodiments of the disclosure, reference is made to the appended drawings, which are not necessarily drawn to scale, and in which reference numerals refer to components of exemplary embodiments of the disclosure. The drawings are illustrative examples, and should not be construed as limiting the disclosure.

FIG. 1 is a schematic illustration of reentrant structures created on a porous PVDF substrate in contact with a liquid droplet, according to an embodiment of the disclosure.

FIG. 2 is a schematic illustration of the iCVD process, according to an embodiment of the disclosure.

FIG. 3A is a schematic rendering of the sequential iCVD approach developed for the fabrication for embodiments of porous omniphobic membranes.

FIG. 3B is a graphical representation of the recorded iCVD pressure and partial pressure profiles of the reactants during the iCVD process according to an embodiment of the disclosure.

FIG. 4A is a set of scanning electron microscopy (SEM) images of pristine and PTFE-coated PVDF membranes according to embodiments of the disclosure, reflecting the iCVD reaction times in each panel.

FIG. 4B is a high magnification cross-section SEM image, taken from the interface between the support PVDF and the assembled reentrant structures with the area between the two dashed lines showing the deposited conformal PTFE layer, for an embodiment of the disclosure.

FIG. 4C is a cross-section SEM image of the omniphobic surface showing the random PTFE reentrant structures assembled on the PVDF support for an embodiment of the disclosure.

FIG. 5 is a set of scanning electron micrographs and the representative FKα energy-dispersive X-ray spectroscopy (EDS) measurements performed on the cross-section of an anodized aluminum oxide (AAO) filter coated at 100 and 1200 mTorr pressures.

FIG. 6A is a graphical representation of the apparent water contact angle on the top and bottom surface of PVDF substrate embodiment, before and after PTFE coating at different pressures.

FIGS. 6B and 6C are C1s core electron spectra of top and the bottom surface of PVDF after PTFE coating at 300 mTorr and 1200 mTorr pressures, respectively, for an embodiment of the disclosure.

FIG. 7A is an atomic force microscopy (AFM) measurement on the PTFE coating on a silicon wafer from a 5×5 μm region of a PTFE coated sample scanned in non-contact mode for an embodiment of the disclosure.

FIG. 7B is an AFM measurement on the PTFE coating on a silicon wafer from a 3×3 μm region of a PTFE coated sample for an embodiment of the disclosure, scanned with a force of around 425 nN in contact mode to create a depression on the sample surface.

FIG. 7C is a graphical representation of the height measurements showing the depression of about 2 nm along the scanned line, scanned in non-contact mode to find the thickness of PTFE deposited on the substrate (˜2 nm) for an embodiment of the disclosure.

FIG. 8A is a graphical representation of the thickness of PTFE deposited on a planar surface (Si wafer) versus deposition times for an embodiment of the disclosure.

FIG. 8B is a graphical representation of data fitting for determining the layer thicknesses for individual data points in FIG. 8A.

FIG. 9 is a set of graphical comparisons of the pore size distribution, calculated by the dry-wet flow method, of control PVDF substrate with that of substrates coated with a conformal layer of PTFE for different lengths of time according to embodiments of the disclosure.

FIG. 10 is a graphical representation of the measured deposition rates of PTFE and PPFDA for embodiments of the disclosure, under different iCVD processing conditions, estimated from QCM data.

FIG. 11A is a plot illustrating the change in the reaction rate for deposition of PTFE for embodiments of the disclosure when both monomer and initiator partial pressures change.

FIG. 11B is a plot illustrating the change in the reaction rate for deposition of PTFE for embodiments of the disclosure when only initiator partial pressure changes.

FIG. 12A is photograph of filament and Aluminum (Al) mask configuration during the QCM measurements. FIG. 12B is a plot of deposition rate versus reaction pressure, with and without an Al mask between filament and sample. FIG. 12C is a schematic illustration of surface templating using a metal mesh during PTFE deposition at high pressure (1200 mTorr) for an embodiment of the disclosure. FIG. 12D is an optical image of the PTFE patterns made using metal mesh for embodiments of the disclosure.

FIG. 13 is a series of X-ray photoelectron spectra at different angles for terminated and unterminated surfaces coated with PPFDA for embodiments of the disclosure.

FIG. 14A is a graphical representation of the CF3/CF2 ratio of terminated and unterminated PTFE surfaces for embodiments of the disclosure, calculated using C1s core electron spectra acquired by angle-resolved X-ray photoelectron spectroscopy (ARXPS) measurements.

FIG. 14B is a graphical representation of the normalized mass gain on the QCM crystals for the terminated and unterminated PTFE surfaces exposed to the PFDA monomer for embodiments of the disclosure.

FIGS. 15A and 15B are graphical representations of QCM accumulative mass data for a terminated and unterminated PTFE surface exposed to PFDA vapor in normalized and deposited mass, respectively, for embodiments of the disclosure.

FIG. 16A is a graphical representation of the comparative ATR-FTIR spectra of PVDF, PTFE, PPFDA, and the materials deposited during iCVD. FIG. 16B is a graphical representation of the comparative XPS survey spectra of a control PVDF surface with PVDF having PTFE reentrant structures (ii) and omniphobic surfaces (iii) for embodiments of the disclosure. FIG. 16C is a C1s core electron XPS spectrum of a control PVDF substrate. FIG. 16D is a C1s core electron spectrum of PTFE thin film deposited on a silicon wafer at P=1200 mTorr for an embodiment of the disclosure. FIG. 16E is a C1s core electron spectrum of the porous PVDF substrate after growing PTFE reentrant structures for embodiments of the disclosure. FIG. 16F is a C1s core electron spectrum collected from the omniphobic surface for an embodiment of the disclosure.

FIG. 17 provides an X-ray photoelectron spectroscopy (XPS), 01 s core electron spectrum of samples coated with PPFDA.

FIGS. 18A-18F are a series of photomicrographs illustrating the morphological change on the PVDF surface after PTFE deposition at different pressures for embodiments of the disclosure.

FIGS. 19A and 19B are XRD patterns of PTFE deposited on a planar substrate at 300 mTorr and 1200 mTorr, respectively, for embodiments of the disclosure.

FIGS. 20A and 20B are top-down scanning electron microscopy (SEM) images of PTFE900-PPFDA and PTFE1200-PPFDA omniphobic membranes, respectively, for embodiments of the disclosure. FIG. 20C is a graph providing the estimated robustness factor for different liquids on the omniphobic surfaces of embodiments of the disclosure. FIG. 20D is an image analysis providing a sample estimation of the second level of roughness factor for embodiments of the disclosure. FIG. 20E are optical images of colored liquid droplets placed on surfaces of embodiments of the disclosure (PTFE900-PPFDA and PTFE1200-PPFDA). The droplets, in order from left to right, are DI water (γ˜72 mN/m), ethylene glycol (γ˜47 mN/m), canola oil (γ˜31.5 mN/m), hexadecane (γ˜26.7 mN/m) and ethanol (γ˜22 mN/m). FIG. 20F is a graphical representation of the equilibrium contact angles of DI water, ethylene glycol, canola oil, hexadecane, and ethanol on the PTFE structures of embodiments of the disclosure, (PTFE900-PPFDA and PTFE1200-PPFDA) having omniphobic surfaces.

FIG. 21 provides a series of photographic images of different liquid droplets (DI water, ethylene glycol, canola oil, hexadecane, and ethanol) before and after impacting the PTFE1200-PPFDA surface of an embodiment of the disclosure.

FIG. 22 is a representative schematic of the direct contact membrane distillation (DCMD) process.

FIG. 23 is a schematic illustration of a custom-made DCMD setup used to evaluate the performance of membranes.

FIG. 24A is a graphical representation providing DCMD results of a control PVDF substrate in a saline feed solution in the absence of SDS. FIG. 24B is a graphical illustration providing DCMD results of a control PVDF substrate in a saline feed solution containing various concentrations of sodium dodecyl sulfate.

FIG. 25 is a graphical representation providing DCMD results of an omniphobic (PTFE1200-PPFDA) membrane in a saline feed solution.

FIG. 26 is a graphical representations providing DCMD results over 24 hours for an omniphobic (PTFE1200-PPFDA) membrane in a saline feed solution containing 0.35 mm of SDS.

FIGS. 27A and 27B are graphical representations providing DCMD performance of a control PVDF support and an omniphobic (PTFE1200-PPFDA) membrane in the desalination of municipal wastewater reverse osmosis (RO) brine.

### DETAILED DESCRIPTION

The present disclosure now will be described more fully hereinafter with reference to examples of embodiments thereof. These examples of embodiments are described so that this disclosure will be thorough and complete and will fully convey the scope of the disclosure to those skilled in the art. Indeed, the disclosure may be embodied in many different forms and should not be construed as limited to the embodiments set forth herein; rather, these embodiments are provided so that this disclosure will satisfy applicable legal requirements. It will be readily apparent to one of ordinary skill in the relevant arts that suitable modifications and adaptations to the compositions, methods, and applications described herein can be made without departing from the scope of any embodiments or aspects thereof.

The compositions and methods provided are exemplary and are not intended to limit the scope of the claimed embodiments. Therefore, it is to be understood that the disclosure is not to be limited to the specific embodiments disclosed and that modifications and other embodiments are intended to be included within the scope of the appended claims. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

All of the various embodiments, aspects, and options disclosed herein can be combined in all variations. The scope of the compositions, formulations, methods, and processes described herein include all actual or potential combinations of embodiments, aspects, options, examples, and preferences herein. Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments. The disclosure includes any of the above-noted embodiments or any combination of two, three, four, or more of the above-noted embodiments, as well as combinations of any two, three, four, or more features or elements set forth in this disclosure, regardless of whether such features or elements are expressly combined in a specific embodiment described herein. This disclosure is intended to be read holistically such that any separable features or elements of the disclosed technologies, in any of its various aspects and embodiments, should be viewed as intended to be combinable unless the context clearly dictates otherwise.

All methods described herein can be performed in any suitable order unless otherwise indicated herein or otherwise clearly contradicted by context. All patents and publications cited herein are incorporated by reference herein for the specific teachings thereof as noted, unless other specific statements of incorporation are specifically provided. The term “about” used throughout this specification is used to describe and account for small fluctuations. For example, the term “about” can refer to less than or equal to ±5%, such as less than or equal to ±2%, less than or equal to ±1%, less than or equal to ±0.5%, less than or equal to ±0.2%, less than or equal to ±0.1% or less than or equal to ±0.05%. All numeric values herein are modified by the term “about,” whether or not explicitly indicated. A value modified by the term “about” of course includes the specific value. For instance, “about 5.0” must include 5.0.

Wetting properties of surfaces can be adjusted using two significant parameters—surface chemistry and roughness. Typically, the wettability of a smooth surface is measured using the equilibrium contact angle, θ, and Young's equation:

$$cos θ = \frac{{γ}_{sv} - {γ}_{sl}}{{γ}_{lv}}$$

where γ refers to the interfacial tension; and s, l, and v refer to the solid, liquid, and vapor phases, respectively. The solid-vapor interfacial tension (γsv) and the liquid-vapor interfacial tension (γlv) are also commonly referred to as the solid surface energy and the liquid surface tension, respectively. According to the Young equation, the solid surfaces having a low surface energy display higher contact angle, and vice versa. Surface roughness, physical properties of both liquid and solid, and process condition (e.g., liquid overhead pressure) are significant factors determining the state of a liquid in contact with a solid surface. Depending on the mentioned properties, a liquid in contact with a nonporous solid surface can take two different states, Wenzel or Cassie-Baxter state. However, controlling the liquid state on porous surfaces is more challenging than the nonporous solid surfaces. In this case, the Wenzel state is defined as the state in which the contacting liquid droplet completely permeates into the surface protrusions and then pores, and fully wets the substrate. The apparent contact angle, θ*, for the Wenzel state can be calculated using the following correlation:

cosθ*=rcosθ

where r is the average surface roughness.

In the Cassie-Baxter state, however, the liquid does not completely wet the surface because pockets of air remain trapped beneath the liquid droplet. The apparent contact angles in the Cassie-Baxter state are typically calculated using the following relation:

cos θ*=ϕₛ(1+cos θ)−1

where ϕs is the fraction of the solid surface in contact with liquid.

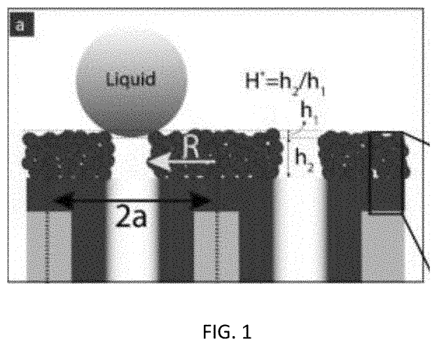

To design porous surfaces with superior wetting properties, control is needed over adjustment to the pore size of the substrate, as it is a determinant factor in omniphobicity of the surface. As disclosed herein, initiated chemical vapor deposition (iCVD) was used to adjust the pore size of the substrate by precisely controlling the thickness and morphology of the coating material. FIG. 1 shows a schematic of a liquid droplet in contact with the reentrant structures created on the porous substrates through the sequential iCVD method as disclosed herein. Once liquid goes in contact with reentrant structures, it partially penetrates between structure and creates a curvature at the air-liquid interface, defined as:

κ=Pₕ/γₗᵥ,

where Pₕ is the external hydraulic pressure. By assuming the structures to have a spherical shape, the penetration depth of liquid in the structures, hl, can be calculated using the following equation:

$${h}_{1} = \frac{1}{κ} ( 1 - cos ( {sin}^{- 1} ( a κ ) ) )$$

where, “a” and “R” are the half of center-to-center distance between surface structures and radius of reentrant structures, respectively. For the present system, “Ra” is defined as:

Ra=[(R+a)/R]²

If liquid penetration into the structures continues up to the height of reentrants structures, h2=R(1−cosθ), the system transits from the Cassie-Baxter to the Wenzel state (total wetting). In designing surfaces with reentrant structures, the approach used by Abraham Marmur (Langmuir 19:8343-8348 (2003)) and Anish Tuteja et al. (Proc. Natl. Acad. Sci. U.S.A 105 (47): 18200-18205 (2008)) was adopted. Accordingly, two factors were used to examine the omniphobic properties of surfaces having reentrant structures. The first was the spacing ratio, “Ra”, which directly affects ϕₛ and thus the apparent contact angle. The second was the robustness factor, H*=h₂/h₁, which determines the robustness of the Cassie-Baxter state relating to the fluid properties, equilibrium contact angle, and surface geometry. Changing “R” (here, the average radius of the reentrant structures) and “2a” (here, the center-to-center distance between the microstructures) has competing effects on the apparent contact angles and the stability of the triple line at the interface. For example, to improve the apparent contact angle, R and consequently ϕ_{s,1}, need to be decreased. However, reducing R has counter effects on the robustness factor. Therefore, to design a robust omniphobic surface having both high apparent contact angle and the stability of the Cassie state, a properly spaced and highly reentrant surface is needed, where both H*>>1 and Ra>>1. Accordingly, ϕ_{s,1}, Ra, and H* can be defined as the following:

$${ϕ}_{s , 1} = {[ R / ( R + a ) ]}^{2}$$

$${H}^{*} = {h}_{2} / {h}_{1} = \frac{2 π [ ( 1 - cos θ ) ] {L}_{cap}}{R ( 2 \sqrt{3} R a - 1 ) ( R a - 1 + 2 sin θ )}$$

where L_{cap} is the capillarity length for the specific liquid defined as:

$${L}_{cap} = \sqrt{\frac{{γ}_{l}}{{ρ}_{0} g}}$$

where, γₗ is the surface energy of the liquids.

In general, to adjust the interspacing parameter Ra, control was gained over the average pore size of the substrate by applying a conformal polymer coating within the substrate, where the pores were narrowed by changing the deposition time. Specifically, iCVD was used to adjust the pore size of the substrate by precisely controlling the thickness and morphology of the coating material. After narrowing the pores, particulate (reentrant) structures were deposited on the substrate surface and created the random reentrant morphologies. The surface energy was subsequently adjusted by further polymer deposition.

Accordingly, one such method for preparing a material having an omniphobic porous surface as disclosed herein generally includes providing a porous substrate, adjusting the average pore size and porosity of the porous substrate, assembling a reentrant structure on the porous substrate, and engineering the surface energy of the reentrant structure. Each of the adjusting, assembling, and engineering utilize initiated chemical vapor deposition (iCVD), performed sequentially. Each of the individual steps of the method is described further herein below.

### Porous Substrate

In an embodiment, the method is performed on a porous substrate. The method is not limited in the nature of the porous substrate utilized. For example, suitable substrates include those having the form of a membrane, a felt, a fabric, or a filter. In some embodiments, the porous substrate is a membrane. In some embodiments, the membrane contains nylon, polycarbonate, or ceramic.

In some embodiments, the porous substrate is a polymer. Suitable polymers include, but are not limited to, poly(vinylidene fluoride) (PVDF), hydrophilic PVDF, polytetrafluoroethylene, polyester, polycarbonate, nylon, cellulose acetate, polysulfones, and the like.

In some embodiments, the porous substrate is one or more of poly(vinylidene fluoride) (PVDF), hydrophilic PVDF, polytetrafluoroethylene, polyester fabric, nylon membrane, cellulose acetate, polycarbonate membrane, a ceramic membrane, an electrospun fiber mat of PVDF, a polysulfone, a carbon nanotube felt, or a titania nanowire filter.

In some embodiments, the porous substrate contains PVDF. In some embodiments, the PVDF is hydrophilic.

### Adjusting the Average Pore Size and Porosity of the Porous Substrate

In a first step, the average pore size and porosity of the porous substrate is adjusted. Generally, the pore size is adjusted by the controlled deposition of a first layer, which coats the surface and the inner walls of the pores. The first layer is present on the substrate as a conformal coating, meaning a thin film which conforms to the contours of the porous substrate. The first layer generally comprises a hydrophobic polymer. Suitable hydrophobic polymers for the first layer include, but are not limited to, polytetrafluoroethylene, poly(perfluorodecyl acrylate), poly(glycidyl methacrylate), poly(1,3,5,7-tetravinyl-1,3,5,7-tetramethylcyclotetrasiloxane), poly(1,3,5-trimethyl-1,3,5-trivinyl cyclotrisiloxane), poly(diethylaminoethyl methacrylate), poly(2,2,3,3-tetrafluoropropyl methacrylate), poly(2,2,3,3,4,4,5,5-octafluoropentyl methacrylate), poly(2,2,3,3,4,4,4-heptafluorobutyl acrylate), poly(2,2,3,4,4,4-hexafluorobutyl acrylate), poly(2,2,3,3-tetrafluoropropyl methacrylate), poly(1h,1h-perfluorooctyl methacrylate), poly(3,3,4,4,5,5,6,6,7,7,8,8,8-tridecafluorooctyl acrylate), poly(3,3,4,4,5,5,6,6,7,7,8,8,9,9,10,10,11,11,12,12,12-heneicosafluorododecyl acrylate), poly(2,2,2-trifluoroethyl acrylate), poly(1,1,1,3,3,3-hexafluoroisopropyl acrylate), poly(2,2,3,3,4,4,4-heptafluorobutyl acrylate), and poly(pentafluorophenyl methacrylate). In some embodiments, the first layer is polytetrafluoroethylene.

The controlled deposition includes performing initiated chemical vapor deposition (iCVD) under reaction-limited conditions with a first monomer in the presence of a first initiator. Suitable monomers include, but are not limited to, hexafluoropropylene oxide, perfluorodecyl acrylate, glycidyl methacrylate, 1,3,5,7-tetravinyl-1,3,5,7-tetramethylcyclotetrasiloxane, 1,3,5-trimethyl-1,3,5-trivinyl cyclotrisiloxane, diethylaminoethyl methacrylate, 2,2,3,3-tetrafluoropropyl methacrylate, 2,2,3,3,4,4,5,5-octafluoropentyl methacrylate, 2,2,3,3,4,4,4-heptafluorobutyl acrylate, 2,2,3,4,4,4-Hexafluorobutyl acrylate, 2,2,3,3-tetrafluoropropyl methacrylate, 1H,1H-perfluorooctyl methacrylate, 3,3,4,4,5,5,6,6,7,7,8,8,8-tridecafluorooctyl acrylate, 3,3,4,4,5,5,6,6,7,7,8,8,9,9,10,10,11,11,12,12,12-heneicosafluorododecyl acrylate, 2,2,2-trifluoroethyl acrylate, 1,1,1,3,3,3-hexafluoroisopropyl acrylate, 2,2,3,3,4,4,4-heptafluorobutyl acrylate, and pentafluorophenyl methacrylate. In some embodiments, the first monomer is hexafluoropropylene oxide.

Suitable initiators include volatile substances which dissociate readily to form radicals. Suitable examples include peroxides and sulfonyl fluorides. In some embodiments, the first initiator is a peroxide or a sulfonyl fluoride. In some embodiments, the first initiator is tert-butyl peroxide, tert-amyl peroxide, or perfluoro-1-butanesulfonyl fluoride.

The initiated chemical vapor deposition (iCVD) of the first monomer can be performed under a variety of substrate temperatures. Suitable substrate temperatures can be varied based on the other parameters, as well as the desired thickness, nature of the monomer, and the like. In some embodiments, the controlled deposition of the first layer is performed at a substrate temperature from about 0° C. to about 100° C., such as from about 10° C. to about 50° C., or from about 10° C. to about 20° C. In some embodiments, the temperature is about 15° C.

The iCVD of the first monomer can be performed under a variety of filament temperatures. iCVD generally utilizes heat from a filament for multiple purposes (e.g., initiator activation, reagent vaporization, adjusting polymerization rate, and the like). In some embodiments, the filament temperature during iCVD of the first monomer (the “first filament temperature”) ranges from about 200° C. to about 500° C., such as from about 200° C., about 250° C., or about 300° C., to about 350° C., about 400° C., about 450° C., or about 500° C. In some embodiments, the first filament temperature ranges from about 300° C. to about 400° C. In some embodiments, the first filament temperature is about 350° C.

The iCVD of the first monomer can be performed under a variety of pressures. The pressure during iCVD of the first monomer (the “first pressure”) can be varied according to the desired layer thickness, the nature of the monomer, the monomer to initiator ratio, filament temperature, and the like. Suitable first pressures range from about 100 mTorr to about 3 Torr. In some embodiments, the first pressure ranges from about 100 mTorr to about 1200 mTorr, such as from about 100, about 200, about 300, about 400, about 500, or about 600, to about 700, about 800, about 900, about 1000, about 1100, or about 1200 mTorr. In some embodiments, the first pressure ranges from about 100 mTorr to about 600 mTorr. In some embodiments, the first pressure ranges from about 200 mTorr to about 400 mTorr. In some embodiments, the first pressure is about 300 mTorr.

The iCVD of the first monomer can be performed using various ratios of monomer to initiator. The ratio can be varied based on the desired layer thickness, the nature of the monomer, the pressure, the filament temperature, and the like. In some embodiments, the ratio of the first monomer to the first initiator ranges from about 0.1 to about 100. In some embodiments, the ratio of the first monomer to the first initiator ranges from about 3 to about 12. In some embodiments, the ratio is adjusted by varying a ratio of monomer to initiator flow rate. In some embodiments, the flow rate ranges from about 0 to about 15.

The iCVD of the first monomer can be performed for varying periods of time. The time is dependent on the various parameters such as flow rates, monomer to initiator ratio, temperature, pressure, and the desired coating thickness. In some embodiments, the time is from about 1 minute to about 60 minutes.

The thickness of the first layer, and consequently, the adjusted pore size, can be varied. The controlled deposition of the first layer is performed under reaction-limited conditions (i.e., controlling the deposition rate based on reactant concentration and pressure). The pore size following the iCVD of the first monomer can be varied depending on the intended use of the omniphobic material. For example, suitable adjusted pore sizes range from about 100 nm to about 100 μm. In some embodiments, the average pore size is from about 100 nm to about 1 μm, such as from about 100, about 200, about 300, about 400, or about 500, to about 600, about 700, about 800, about 900, or about 1000 nm. In some embodiments, the average pore size is from about 300 to about 500 nm.

### Assembling a Reentrant Structure

In a second step, a reentrant structure is assembled. Generally, the reentrant structure is assembled by the controlled deposition of a second layer, which extends up from the first layer as a non-conformal coating (i.e., the second layer extends from the outermost first layer).

The second layer generally includes a hydrophobic polymer. Suitable hydrophobic polymers for the second layer include, but are not limited to, polytetrafluoroethylene, poly(perfluorodecyl acrylate), poly(glycidyl methacrylate), poly(1,3,5,7-tetravinyl-1,3,5,7-tetramethylcyclotetrasiloxane), poly(1,3,5-trimethyl-1,3,5-trivinyl cyclotrisiloxane), poly (diethylaminoethyl methacrylate), poly(2,2,3,3-tetrafluoropropyl methacrylate), poly(2,2,3,3,4,4,5,5-octafluoropentylmethacrylate), poly(2,2,3,3,4,4,4-heptafluorobutyl acrylate), poly(2,2,3,4,4,4-hexafluorobutyl acrylate), poly(2,2,3,3-tetrafluoropropyl methacrylate), poly(1h,1h-perfluorooctyl methacrylate), poly(3,3,4,4,5,5,6,6,7,7,8,8,8-tridecafluorooctyl acrylate), poly(3,3,4,4,5,5,6,6,7,7,8,8,9,9,10,10,11,11,12,12,12-heneicosafluorododecyl acrylate), poly(2,2,2-trifluoroethyl acrylate), poly(1,1,1,3,3,3-hexafluoroisopropyl acrylate), poly(2,2,3,3,4,4,4-heptafluorobutyl acrylate), and poly(pentafluorophenyl methacrylate). In some embodiments, the second layer is polytetrafluoroethylene. In some embodiments, the first and second layers are both polytetrafluoroethylene.

The controlled deposition of the second layer includes performing iCVD under diffusion-limited conditions with a second monomer in the presence of a second initiator. Suitable second monomers include, but are not limited to, hexafluoropropylene oxide, perfluorodecyl acrylate, glycidyl methacrylate, 1,3,5,7-tetravinyl-1,3,5,7-tetramethylcyclotetrasiloxane, 1,3,5-trimethyl-1,3,5-trivinyl cyclotrisiloxane, diethylaminoethyl methacrylate, 2,2,3,3-tetrafluoropropyl methacrylate, 2,2,3,3,4,4,5,5-octafluoropentyl methacrylate, 2,2,3,3,4,4,4-heptafluorobutyl acrylate, 2,2,3,4,4,4-Hexafluorobutyl acrylate, 2,2,3,3-tetrafluoropropyl methacrylate, 1H,1H-perfluorooctyl methacrylate, 3,3,4,4,5,5,6,6,7,7,8,8,8-tridecafluorooctyl acrylate, 3,3,4,4,5,5,6,6,7,7,8,8,9,9,10,10,11,11,12,12,12-heneicosafluorododecyl acrylate, 2,2,2-trifluoroethyl acrylate, 1,1,1,3,3,3-hexafluoroisopropyl acrylate, 2,2,3,3,4,4,4-heptafluorobutyl acrylate, and pentafluorophenyl methacrylate. In some embodiments, the second monomer is hexafluoropropylene oxide. In some embodiments, the first and second monomers are both hexafluoropropylene oxide.

Suitable second initiators include volatile substances which dissociate readily to form radicals. Suitable examples include peroxides and sulfonyl fluorides. In some embodiments, the second initiator is a peroxide or a sulfonyl fluoride. In some embodiments, the second initiator is tert-butyl peroxide, tert-amyl peroxide, or perfluoro-1-butanesulfonyl fluoride. In some embodiments, the first and second initiator are both tert-butyl peroxide, tert-amyl peroxide, or perfluoro-1-butanesulfonyl fluoride.

The initiated chemical vapor deposition (iCVD) of the second monomer can be performed under a variety of substrate temperatures. Suitable substrate temperatures can be varied based on the other parameters, as well as the desired thickness, nature of the monomer, and the like. In some embodiments, the controlled deposition of the second layer is performed at a substrate temperature from about 0° C. to about 100° C., such as from about 10° C. to about 50° C., or from about 10° C. to about 20° C. In some embodiments, the temperature is about 15° C.

The iCVD of the second monomer can be performed under a variety of filament temperatures. In some embodiments, the filament temperature during iCVD of the second monomer (the “second filament temperature”) ranges from about 200° C. to about 500° C., such as from about 200° C., about 250° C., or about 300° C., to about 350° C., about 400° C., about 450° C., or about 500° C. In some embodiments, the second filament temperature is from about 300° C. to about 400° C. In some embodiments, the second filament temperature is about 350° C.

The iCVD of the second monomer can be performed under a variety of pressures. The controlled deposition of the second layer is performed under diffusion-limited conditions (i.e., controlling the deposition rate based on pressure, and using a higher pressure than for the conformal coating of the first layer). The pressure during iCVD of the second monomer (the “second pressure”) can be varied according to the desired layer thickness, the nature of the monomer, the monomer to initiator ratio, filament temperature, and the like. Suitable second pressures are from about 600 mTorr to about 3 Torr. In some embodiments, the second pressure ranges from about 600 mTorr to about 1200 mTorr, such as from about 600, about 700, about 800, or about 900, to about 1000, about 1100, or about 1200 mTorr.

The iCVD of the second monomer can be performed using various ratios of monomer to the initiator. The ratio can be varied based on the desired layer thickness, the nature of the monomer, the pressure, the filament temperature, and the like. In some embodiments, the ratio of the second monomer to the second initiator ranges from about 0.1 to about 100. In some embodiments, the ratio of the second monomer to the second initiator ranges from about 3 to about 12. In some embodiments, the ratio is adjusted by varying a ratio of monomer to initiator flow rate. In some embodiments, the flow rate is from about 0 to about 15.

The iCVD of the second monomer can be performed for varying periods of time. The time is dependent on the various parameters such as flow rates, monomer to initiator ratio, temperature, pressure, and the desired coating thickness. In some embodiments, the time is from about 1 minute to about 60 minutes.

The thickness of the second layer can vary, and can be adjusted based on parameters such as monomer concentration, pressure, temperature, and time. For example, the thickness of the second layer can be adjusted between about 100 nm and about 3000 nm. In some embodiments, the thickness ranges from about 100 nm, about 200 nm, about 300 nm, about 400 nm, about 500 nm, about 600 nm, about 700 nm, about 800 nm, about 900 nm, or about 1000 nm, to about 1500 nm, about 2000 nm, about 2500 nm, or about 3000 nm. The coverage density of the second layer can vary. For example, in some embodiments, the coverage density ranges from about 0.1 to about 0.5.

### Engineering the Surface Energy of the Reentrant Structure

In a third step, the surface energy of reentrant structure is engineered. Generally, the engineering includes grafting a third layer onto the second layer. The third layer generally contains a hydrophobic polymer. Suitable hydrophobic polymers for the third layer include, but are not limited to, poly(perfluorodecyl acrylate) (PPFDA), poly(1,3,5,7-tetravinyl-1,3,5,7-tetramethylcyclotetrasiloxane), poly(1,3,5-trimethyl-1,3,5-trivinyl cyclotrisiloxane), poly(2,2,3,3,4,4,4-heptafluorobutyl methacrylate), poly(3,3,4,4,5,5,6,6,7,7,8,8,8-tridecafluorooctyl methacrylate), poly(2,2,3,3-tetrafluoropropyl methacrylate), poly(2,2,3,3,4,4,5,5-octafluoropentyl methacrylate), poly(2,2,3,3,4,4,4-heptafluorobutyl acrylate), poly(2,2,3,4,4,4-hexafluorobutyl acrylate), and poly(2,2,3,3-tetrafluoropropyl methacrylate). The grafting is performed with iCVD under reaction-limited conditions with a third monomer in the presence of a third initiator. Suitable third monomers include, but are not limited to perfluorodecyl acrylate (PFDA), 1,3,5,7-tetravinyl-1,3,5,7-tetramethylcyclotetrasiloxane, 1,3,5-trimethyl-1,3,5-trivinyl cyclotrisiloxane, 2,2,3,3,4,4,4-heptafluorobutyl methacrylate, 3,3,4,4,5,5,6,6,7,7,8,8,8-tridecafluorooctyl methacrylate, 2,2,3,3-tetrafluoropropyl methacrylate, 2,2,3,3,4,4,5,5-octafluoropentyl methacrylate, 2,2,3,3,4,4,4-heptafluorobutyl acrylate, 2,2,3,4,4,4-hexafluorobutyl acrylate, and 2,2,3,3-tetrafluoropropyl methacrylate. In some embodiments, the third monomer is PFDA.

Suitable third initiators include volatile substances which dissociate readily to form radicals. Suitable examples include peroxides and sulfonyl fluorides. In some embodiments, the third initiator is a peroxide or a sulfonyl fluoride. In some embodiments, the third initiator is tert-butyl peroxide, tert-amyl peroxide, or perfluoro-1-butanesulfonyl fluoride. In some embodiments, the first, second, and third initiator are all tert-butyl peroxide, tert-amyl peroxide, or perfluoro-1-butanesulfonyl fluoride.

The initiated chemical vapor deposition (iCVD) of the third monomer can be performed under a variety of substrate temperatures. Suitable substrate temperatures can be varied based on the other parameters, as well as the desired thickness, nature of the monomer, and the like. In some embodiments, the controlled deposition of the third layer is performed at a substrate temperature from about 0° C. to about 100° C., such as from about 10° C. to about 50° C., or from about 10° C. to about 20° C. In some embodiments, the temperature is about 15° C.

The iCVD of the third monomer can be performed under a variety of filament temperatures. In some embodiments, the filament temperature during iCVD of the third monomer (the “third filament temperature”) ranges from about 200° C. to about 500° C., such as from about 200° C., about 250° C., or about 300° C., to about 350° C., about 400° C., about 450° C., or about 500° C. In some embodiments, the third filament temperature ranges from about 300° C. to about 400° C. In some embodiments, the third filament temperature is about 350° C.

The iCVD of the third monomer can be performed under a variety of pressures. The pressure during iCVD of the third monomer (the “third pressure”) can be varied according to the desired layer thickness, the nature of the monomer, the monomer to initiator ratio, filament temperature, and the like. Suitable first pressures range from about 100 mTorr to about 3 Torr. In some embodiments, the third pressure ranges from about 100 mTorr to about 1200 mTorr, such as from about 100 mTorr, about 200 mTorr, about 300 mTorr, about 400 mTorr, about 500 mTorr, or about 600 mTorr, to about 700 mTorr, about 800 mTorr, about 900 mTorr, about 1000 mTorr, about 1100 v, or about 1200 mTorr. In some embodiments, the third pressure ranges from about 100 mTorr to about 600 mTorr. In some embodiments, the third pressure ranges from about 200 mTorr to about 400 mTorr. In some embodiments, the third pressure is about 300 mTorr.

The iCVD of the third monomer can be performed using various ratios of monomer to initiator. The ratio can be varied based on the desired layer thickness, the nature of the monomer, the pressure, the filament temperature, and the like. In some embodiments, the ratio of the third monomer to the third initiator ranges from about 0.1 to about 100. In some embodiments, the ratio of the third monomer to the third initiator ranges from about 3 to about 12. In some embodiments, the ratio is adjusted by varying a ratio of monomer to initiator flow rate. In some embodiments, the flow rate ranges from about 0 to about 15.

The iCVD of the third monomer can be performed for varying periods of time. The time is dependent on the various parameters such as flow rates, monomer to initiator ratio, temperature, pressure, and the desired coating thickness. In some embodiments, the time ranges from about 1 minute to about 60 minutes.

In some embodiments, the method as disclosed herein is performed as a continuous process. To achieve this, rollers were installed and the chemicals were metered orthogonal to the direction of the substrate movement. After completing the first deposition, the direction of substrate movement was reversed by rewinding the roller rotation and the second deposition was conducted to construct the nanostructured layer on the substrates. Following this, the direction of the rotation on the rollers was rewound one last time and the third layer was applied to create an omniphobic surface.

### Omniphobic Surfaces

The method as disclosed herein provides materials having an omniphobic surface, meaning that the surface of such materials repels virtually all liquids, regardless of polarity. The method as disclosed herein further allows tailoring of the surface topology, resulting in surfaces with differing degrees of wettability. Specifically, varying reaction pressure in iCVD deposition of the second and third layers enables the preparation of surfaces with distinct wettability. Accordingly, the disclosed method can be utilized to prepare a wide variety of materials with omniphobic surface features. Such materials can be useful in applications, such as direct contact membrane distillation (DCMD), carbon dioxide capture, microfluidic devices, water-energy harvesting, chemical shielding, and various separation and purification methodologies.

Certain embodiments are now described with reference to the following examples. Before describing several exemplary embodiments, it is to be understood that the disclosure is not limited to the details of construction or process steps set forth in the following description. The technology is capable of other embodiments and of being practiced or being carried out in various ways.

### EXAMPLES

Materials and Chemicals

Polyvinylidene fluoride (PVDF) (MW: 530 kDa), triethyl phosphate (TEP, 97%), perfluorobutane sulfonyl fluoride (96%), and hexadecane (99%) were purchased from Sigma Aldrich. Sodium chloride (NaCl, >99%), hexanes (>98.5%), ethanol (99.5%), and isopropyl alcohol (IPA, >99.5%) were purchased from Fisher Scientific. Ethylene glycol (99.5%) was purchased from ACROS Organics. Canola oil was purchased from Wesson Oil. Hexafluoropropylene oxide (HFPO) was purchased from Oakwood Products. 1H,1H,2H,2H-perfluorodecyl acrylate (PFDA, 97%) was obtained from Frontier Scientific. Deionized (DI) water was obtained from a Simplicity® ultrapure water purification system (Millipore, Billerica, Mass.). Ultrapure nitrogen was purchased from Matheson Gas Company. Perfluorobutane sulfonyl fluoride (PBSF, 96%) and hydroquinone (HQ) (>99%) were purchased from Sigma-Aldrich. Isopropyl alcohol (IPA, ACS grade), glycerol (certified ACS), and sodium chloride (NaCl, ACS grade) were purchased from Fisher Scientific. Ethylene Glycol (99.5%) was purchased from ACROS Organics.

### General Procedures

Scanning Electron Microscopy (SEM). Scanning electron microscopy (SEM) images were taken using an FEI Helios NanoLab 660 microscope. To obtain the cross-section images, wet membranes were freeze-fractured using liquid nitrogen. The samples were then dried in a vacuum oven at a temperature of 60° C. for three hours to remove the residual moisture. After drying, the samples were cut to size, mounted on the SEM stub, and coated with 60 nm of gold, using a Ted Pella sputtering machine (108-Auto). The samples were transferred to the microscope for measurements.

Fourier-Transform Infrared Spectroscopy (FTIR). FTIR measurements were performed using the attenuated total reflection (ATR) module of the Bruker Alpha-p IR spectrometer. The ATR Diamond crystal was cleaned using pure isopropyl alcohol before every measurement. A small (1 cm×1 cm) piece of the sample was cut to size and placed on the crystal of the ATR module. The spectra were collected with a resolution of 4 cm-1 and averaged over 24 scans.

Atomic Force Microscopy (AFM). AFM measurements were carried out under ambient conditions using a commercial AFM system (MFP3D, Asylum Research). Diamond-coated AFM tips (CDT-NCHR, Nanosensors) with a nominal resonant frequency (f0) of 400 kHz, tip radius of 100-200 nm, and a spring constant of 80 N/m were utilized. In contact mode, the measurements were performed over a 15 μm2 at a constant speed of 200 nm/s and under a constant loading force of 425 nN. The measurements of peak force tapping (non-contact) mode were performed over 25 μm².

X-ray Photoelectron Spectroscopy (XPS). XPS measurements were performed using a K-alpha XPS system (ThermoFisher Scientific). Survey XPS spectra were acquired at 100 W with a pass energy of 200 eV over the range of 0-1350 eV with 1 eV resolution, 100 ms dwell time, and averaged over three scans. High-resolution XPS spectra of C 1s, F 1s, and O 1s core electrons were acquired over a spot of approximately 400 μm with 50 W beam power and averaged five times with 0.1 eV resolutions at 50 eV pass energy with 100 ms dwell time.

Contact Angle Measurements. The liquid contact angle on the membrane surfaces was measured using an optical tensiometer (Rame-hart, Model 590) and the sessile drop method. Accordingly, a 5 μL liquid droplet was placed on a dry membrane sample and the contact angle was measured within one minute. The measurements were performed on three random points on each sample; the data points show the average value of the measurements with one standard deviation.

General Procedures for Initiated Chemical Vapor Deposition (iCVD)

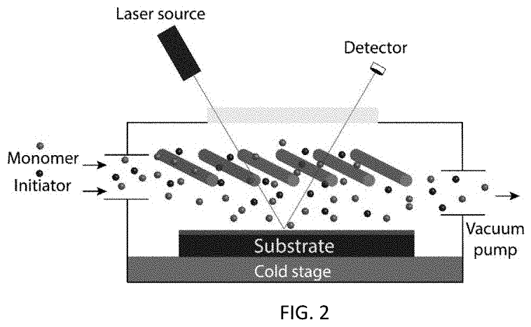

The assembly of flexible reentrant structures on porous hydrophobic poly(vinylidene fluoride) (PVDF) substrates and the subsequent adjustment of the surface energy was performed by the sequential initiated chemical vapor deposition (iCVD) of poly(tetrafluoroethylene) (PTFE) and poly(1H,1H,2H,2H-perfluorodecyl acrylate) (PPFDA on the substrates. In iCVD, as shown in FIG. 2, the synthesis of polymers on the substrate surface takes place in two key steps: (1) transport dynamics of reactants from the vapor phase to the substrate, and (2) polymerization reactions on the surface that leads to the formation of thin films. The properties of deposited thin films can be controlled by adjusting the polymerization reaction parameters (e.g., substrate and filament temperatures, and monomer to initiator ratio) and/or the vapor phase transport of species. Without wishing to be bound by theory, it is believed that the reaction parameters possess the most critical role in the physical properties of the deposited thin films, as they alter the kinetic regime of the reactions.

### Example 1. Design and Fabrication of Porous Omniphobic Surfaces

### Example 1A. Fabrication of Porous PVDF Support

Porous hydrophobic PVDF substrates were prepared using the following procedure. A polymer solution was prepared by dissolving 12 wt. % PVDF (530 kDa) pellets in triethyl phosphate (TEP). The solution was stirred overnight at 125° C. and 400 RPM on a hot plate (Corning Inc.). The polymer solution was left to rest at room temperature for at least six hours to cool and become free of air bubbles. Then, it was cast on a glass plate at a speed of approximately 5 cm/s using a casting knife (Gardco). The casting process was done at room temperature (22° C.) with 52% relative humidity. The film thickness was controlled by adjusting the gate height of the casting knife. After casting, within five seconds, the glass plate was submerged in a non-solvent bath to induce the non-solvent induced phase separation. The coagulation bath was composed of 70 vol % isopropanol (IPA) in deionized (DI) water. The glass plate was left in the coagulation bath for five minutes then transferred to a pure DI water bath and stored overnight to remove the residual solvent. After solvent removal, the formed membranes were rinsed with ethanol and then dried for 12 hours in a temperature-controlled oven (Quincy Lab, 20 GC) set at 75° C.

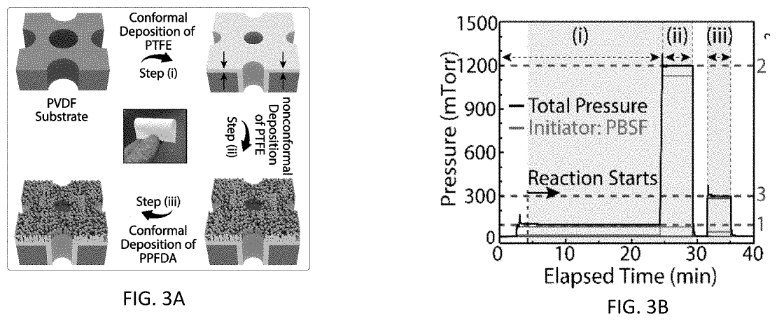

To render PVDF porous substrates omniphobic through a semi-continuous process iCVD, the pore size was adjusted, reentrant structures assembled, and surface energy modified. Following the preparation of the PVDF substrate (Example 1A), the iCVD method consisted of three consecutive steps: (i) adjusting the average pore size and porosity of the substrate, (ii) assembling the reentrant structure, and (iii) engineering the surface energy (Examples 1B-1D, below). A schematic representation of the nanofabrication method is presented in FIG. 3A.

### Example 1B. Initiated Chemical Vapor Deposition (iCVD)-Adjusting the Average Pore Size and Porosity of the Substrate with PTFE Coating

The morphology and chemistry of porous substrates were modified through sequential controlled deposition of polytetrafluoroethylene (PTFE). A conformal coating of PTFE (Step i) was used to fill and narrow the substrate pores. The iCVD of polytetrafluoroethylene (PTFE), was performed in a custom-made initiated chemical vapor deposition (iCVD) reactor with a total volume of ˜3600 cm³. To perform the PTFE deposition, hexafluoropropylene oxide (HFPO) and perfluorobutanesulfonyl fluoride (PBSF) were metered into the reactor using a mass flowmeter (MKS Instruments) and a precision needle valve (Swagelok); flow rates for HFPO and PBSF were set at 12 and 1 sccm, respectively. The backside-cooled stage was maintained at 15° C. and the Phosphor-Bronze filament (Good Fellow), suspended ˜20 mm above the substrate, was heated to about 350° C. A downstream throttle valve and a pressure controller (MKS Instruments) were connected to a dry vacuum pump (Edwards Vacuum) to maintain a constant pressure at the desired set point (e.g., from about 100-1200 mTorr). The reaction was initiated by thermal pyrolysis of PBSF in the gas phase using the heated filament array, followed by the initiation and propagation of polymer chains adsorbed on the back-cooled substrate. To achieve conformal coating through the thickness of the substrate, the process was adjusted to be reaction limited (ca.4 nm/min) at a very low pressure, 100 mTorr.

At the end of the iCVD sequence, the monomer introduction was first stopped and initiator allowed to flow into the reactor for 30 seconds to terminate the growing polymer chains. Then, the filament was turned off, the initiator flows were stopped, and the reactor was evacuated to the base pressure (˜18 mTorr). After deposition, the samples were left under vacuum for an additional 15 minutes to remove unreacted monomer and initiator molecules.

### Example 1C. Initiated Chemical Vapor Deposition (iCVD)-Adjusting the Morphology of the Substrate with PTFE Coating

For the second layer (Step ii), assembly of a random reentrant structure of PTFE was performed. The process was performed as in Example 1B, but was transitioned to a diffusion-limited regime by increasing the reaction pressure by more than one order of magnitude (12-fold; 1200 mTorr), leading to a non-conformal coating of PTFE.

At the end of the iCVD sequence, the monomer introduction was first stopped and initiator allowed to flow into the reactor for 30 seconds to terminate the growing polymer chains. Then, the filament was turned off, the initiator flows were stopped, and the reactor was evacuated to the base pressure (˜18 mTorr). After deposition, the samples were left under vacuum for an additional 15 minutes to remove unreacted monomer and initiator molecules.

### Example 1D. Initiated Chemical Vapor Deposition (iCVD)—Surface Energy-Adjusted Conformal PPFDA Coating

The morphology and chemistry of porous substrates was modified through controlled deposition of poly(1H,1H,2H,2H-Perfluorodecyl acrylate (PPFDA) (Step (iii)). In Step (iii), the surface energy of the assembled particulate-like structures of PTFE from Example 1C was adjusted by grafting a highly fluorinated polymer on the top of the PTFE structures. To achieve this, a conformal layer of PPFDA was grafted onto the PTFE structures prepared in Example 1C. The iCVD of poly(1H,1H,2H,2H-perfluorodecyl acrylate) (PPFDA), was performed in the custom-made initiated chemical vapor deposition (iCVD) reactor described in Example 1B. Specifically, PFDA and PBSF were metered into the iCVD reactor using precision needle valves (Swagelok). The flow rates of PFDA and PBSF were set to 0.26 and 1 sccm, respectively. The backside-cooled stage was maintained at 15° C. and the filament temperature was set at 350° C. The iCVD of PPFDA was performed for three minutes at a total pressure of 300 mTorr. FIG. 3B shows the total pressure and partial pressures of the reactants as a function of time.

At the end of the iCVD sequence, the monomer introduction was first stopped and initiator allowed to flow into the reactor for 30 seconds to terminate the growing polymer chains. Then, the filament was turned off, the initiator flows were stopped, and the reactor was evacuated to the base pressure (˜18 mTorr). After deposition, the samples were left under vacuum for an additional 15 minutes to remove unreacted monomer and initiator molecules.

### Example 2. PVFDF Substrate with PTFE Coating

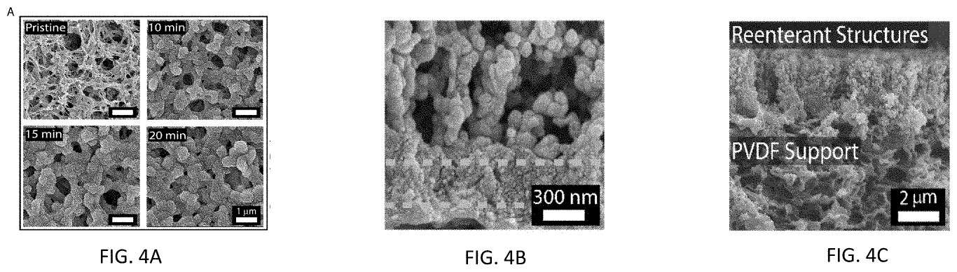

A PVDF substrate, prepared according to Example 1A, was coated with PTFE according to the general procedures of Examples 1B-1D. FIG. 4A provides scanning electron microscope images of the surfaces, before and after coating with PTFE for varying lengths of time. FIGS. 4B and 4C show the structure of the PTFE layer, which was mostly composed of nanoscale particles of PTFE. The formation of these structures was achieved by introducing a step-change in the reactor pressure, where the iCVD process transitioned from a reaction-limited to a diffusion-limited one. This transition enabled limiting the growth of PTFE to the outermost surface of the membranes. The penetration depth of coating into the substrate was adjusted by controlling the ratio of reaction and diffusion rates in the porous substrate. This ratio can be defined as a, which is similar to the second Damkohler number, yet defined for a porous media. Increasing the pressure makes the deposition into the porous substrate a diffusion-limited process. At the same time, the reaction rate increases with pressure. These phenomena create a preferential coating on the outer most layer of PTFE substrate (non-conformal coating). To theoretically explain why increasing the reaction pressure results in a non-conformal coating through the thickness of the substrate, the mean free path was calculated, along with substrate length scale, and tortuosity for the reaction conditions. The mean free path of the monomer can be defined using the following equation (Equation 1):

$$\overline{l} = \frac{{k}_{B} T}{\sqrt{2} π {pd}_{m}^{2}} \qquad ( Equation 1 )$$

where k_{B} is the Boltzmann constant, T is the temperature (here, the temperature of the cold stage), p is the partial pressure of reactant (e.g., monomer), and dₘ is the kinetic diameter of the reactants. For example, the kinetic diameter of the PTFE monomer, hexafluoropropylene oxide (HFPO), was calculated to be ˜6 Å (Chem3D). The calculations showed that the mean free path of HFPO molecules decreased from ˜30 cm to ˜3 cm when the pressure of reactor changed from 100 mTorr to 1200 mTorr. Consequently, considering an average pore size of ˜589 nm, the Knudsen number changes from 6×10⁵ to 4.5×10⁴ for the PVDF substrate. The tortuosity of the PVDF substrate was estimated, using computational fluid dynamics (CFD) simulations, to be around 3.5. Considering the substrate tortuosity (τ) of ˜3.5, average thickness (δ) of ˜90 μm, and an average pore diameter of ˜589 nm, the effective pore aspect ratio (L/D=τδ/D) of PVDF substrate was calculated to be ˜540. Hence, in this case, a high aspect ratio of the PVDF substrate added to a small mean free path of molecules at higher pressures led to an asymmetric deposition through the thickness of the membrane, where the intensity of the coating was the maximum on the top surface of the substrate and decreased through the substrate thickness.

### Example 3. Anodized Aluminum Oxide Substrate with PTFE Coating

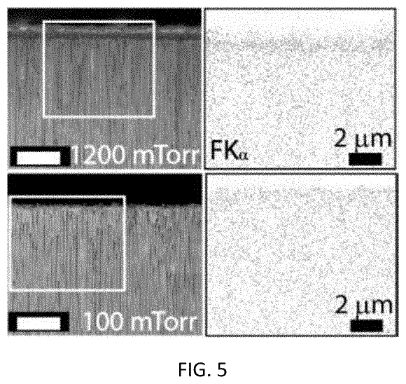

To show the transition between reaction-limited and diffusion-limited regimes by X-ray spectroscopy (EDS), the deposition experiment was performed on inorganic filters (anodized aluminum oxide (AAO) filters) as the substrate, and coating performed at two distinct pressures of 100 and 1200 mTorr. The scanning electron micrographs and the representative EDS maps, collected from the cross-section of AAO disks, are shown in FIG. 5. Here, the fluorine signal was mostly confined to the vacuum interface when the reactor pressure was chosen within the range for which the process is diffusion-limited.

### Example 4. PVDF Substrates with PTFE Coating; Different PTFE Deposition Pressures

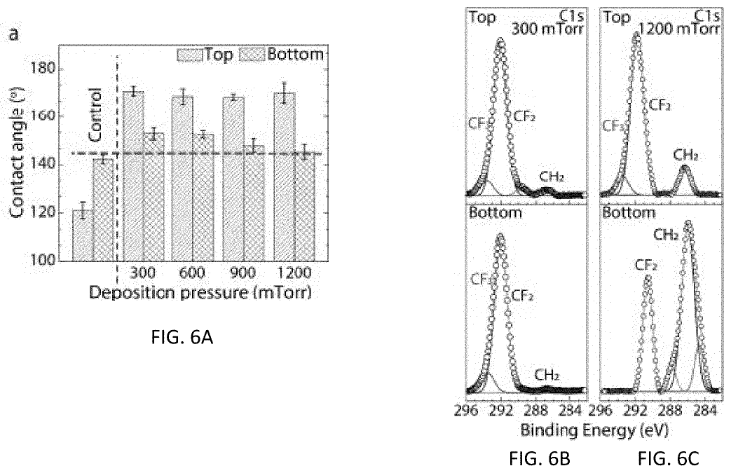

To show that at a diffusion-limited regime, the coating did not reach to the other side of the porous PVDF substrate, the water contact angle on both top and backside of the PVDF substrate was measured after PTFE deposition at different pressures. To prevent direct exposure of reactants to the bottom surface of the substrate during the iCVD process, the substrate was taped down on the cleaned iCVD cold stage using Kapton tape (Mc-Master Carr) such that only the top surface is open to the reaction environment. FIG. 6A shows the variation of water contact angle on both the top and backside of the PVDF substrate coated with PTFE at different pressures. As seen, the contact angle of the top surface of the membrane remained in the same range (>1650) after the PTFE coating. In contrast, the water contact angle on the bottom surface of the membrane decreased by increasing the pressure and approached that of the pristine PVDF substrate when the pressure of reaction reached 1200 mTorr. This observation indicated that at P=1200 mTorr, the coating did not penetrate through the PVDF support, and the backside of the membrane remained pristine.

To confirm, X-ray photoelectron spectroscopy (XPS) measurements were performed on the top and bottom surface of PVDF substrate coated with PTFE at low (300 mTorr) and high (1200 mTorr) pressures. As displayed in FIG. 6B, the C 1 s core electron spectra of both top and the bottom surface of PVDF coated with PTFE matches to the C1s signal of control PTFE. On the other hand, the C1s core electron spectra on the bottom surface of the support coated at 1200 mTorr matched the C1s signal of control PVDF (FIG. 6C). It indicated that, when the pressure of reaction was high (e.g., 1200 mTorr), the system became diffusion-limited, and the coating did not penetrate the substrate.

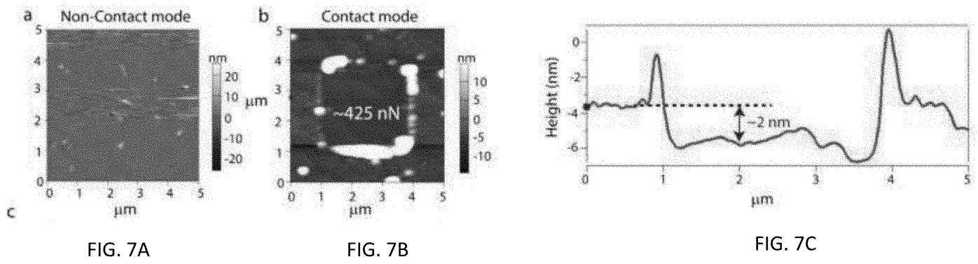

The thickness measurements were performed on a 5×5 μm region of the PTFE coated sample scanned in non-contact mode, shown in FIG. 7A. Then, as displayed in FIG. 7B, a 3×3 μm area of the sample was scanned with a force of around 425 nN in contact mode with a constant speed of 200 nm/s to create a depression on the sample surface. Finally, a 5 μm line was scanned in non-contact mode to find the thickness of deposited PTFE on the substrate. In FIG. 7C, the height measurements showed the depression of about 2 nm along the scanned line.

### Example 5. Si Substrates with PTFE Coating; Different PTFE Deposition Times

To correlate the coating thickness with deposition time, PTFE was deposited on a planar surface (Si wafer) for different time periods. For the films deposited at low-pressure (<300 mTorr), the change of thickness was calibrated as a function of the deposition time using spectroscopic ellipsometry (SE). SE is a nondestructive optical measurement which uses changes in the refractive index to deduce the film thickness from fitting to an optical model. SE relies on wavelength-dependent changes in phase angle and intensity of circularly polarized light as it impinges on a sample. The measurements are more detailed and reliable if repeated at multiple angles of incidence (i.e., variable angle SE (VASE)).

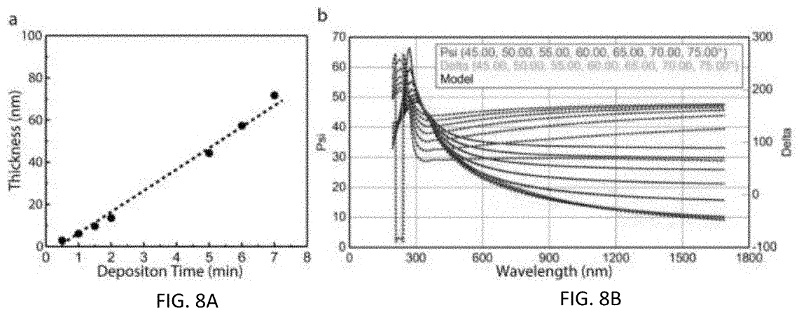

Before the deposition of PTFE, the thickness of native oxide on the control Si wafer samples was estimated by measuring the changes in the polarization state of the light, impinging on the sample surface at different angles (45-75°) at different wavelengths (200-1800 nm). The thickness was estimated by fitting the data collected at different angles and wavelengths using the standard Cauchy model and the CompleteEASE Software (J. A. Woollam Inc.) The Cauchy model assumes zero light absorption (k=0) which is reasonable when dealing with thin dielectric films. The Cauchy model can be written as Equation 1:

$$n ( λ ) = A + \frac{B}{{λ}^{2}} + \frac{C}{{λ}^{4}} + … \qquad ( Equation 2 )$$

where n and λ are the refractive index and wavelength, respectively. Here, A, B, and C are the fitting parameters of the model. FIG. 8A illustrates the PTFE thickness for different deposition times (P=200 mTorr and substrate temperature of 15° C.). As seen, the thickness growth on the planar Si wafer surface was linear with deposition time. FIG. 8B shows a model of fitted data in the CompleteEASE software.

### Example 6. PVDF Substrates with PTFE Coating; Adjusting Pore Sizes

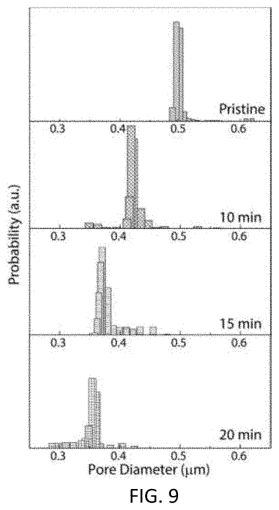

To adjust the pore size of the porous PVDF substrates, PTFE deposition was performed according to Example 1B at low pressure (100 mTorr). The pore size distribution was evaluated by a wet-dry flow method using a custom-built capillary flow porometer. For this purpose, a stainless-steel filter holder (13 mm, Advantec) having a flat metal mesh with an effective area of 0.9 cm2 (50% open) was used. The nitrogen flow was flown into the filter holder at a known pressure. A digital pressure regulator (Control Air Inc., 900-CHA) was used to control the pressure of nitrogen. The pressure across the membrane and gas flow through the membrane was recorded by a pressure transducer (Honeywell, px2an1xx100psaax) and a flow meter (Omega Engineering, FMA1720), respectively. To perform the measurements, the membranes were punched into 13 mm diameter circles. Then, the samples were wetted using a commercial wetting liquid having a low surface tension (16 mN/m) and vapor pressure (399 Pa at 298 K). The pore size distribution was acquired by using a method described elsewhere. FIG. 9 shows the pore size distribution, acquired through the dry-wet flow method, for pristine PVDF support (control) and substrate coated with PTFE for 10, 15, and 20 minutes. As shown, when the deposition time increased, the distribution curve shifted toward a smaller pore size.

### Example 7. iCVD Deposition Rate Study

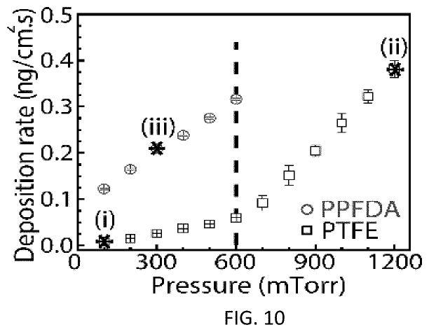

To understand the effect of processing parameters during the iCVD reactions, the deposition rate of polymers was measured by recording the mass gain on a quartz crystal microbalance (QCM). FIG. 10 shows the deposition rates of PTFE and PPFDA as a function of operating pressure for the entire processing range disclosed herein. In FIG. 10, the asterisks refer to the operating conditions used for each step of the fabrication scheme. In a typical iCVD process, the adsorbed primary radicals (I•), created by the thermal decomposition of the PBSF molecules, react with the adsorbed monomer molecules (M). Subsequently, the product of this reaction, the created radicals (M•) on the surface, react with other adsorbed monomer molecules (M), resulting in chain propagation.

As previously reported, the mechanistic modeling of iCVD suggests a linear correlation between the surface concentration of monomers (M) and the deposition rate. However, here two different regimes were observed marked by a distinct shift in the deposition rate. Without wishing to be bound by theory, this phenomenon was attributed to the high reactivity of CF radicals generated in the gas phase. It was hypothesized that most of the monomer molecules and primary radicals (I•) collide and react in the gas phase when the pressure exceeds a critical limit of (˜800 mTorr). As a result, gas-phase reactions become dominant, and the hot wire filaments act as a source for the deposition of particulate-like PTFE structures onto the substrate surface.

### Example 8. Kinetics of PTFE Deposition

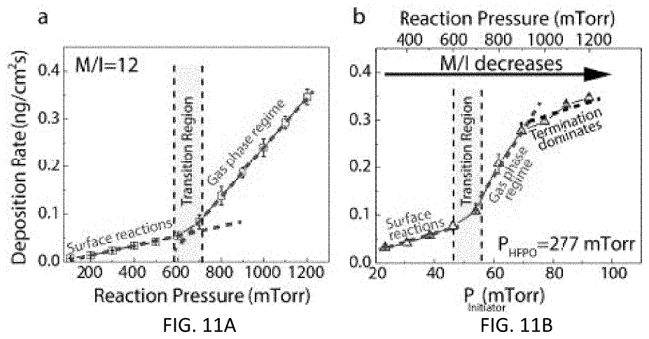

To study the kinetics of PTFE deposition, while transitioning the process from a reaction-limited condition (at low pressures) to a diffusion-limited state (at high pressures), the deposition rate was measured using quartz crystal microbalance (QCM). As shown in FIG. 11A, where the ratio of monomer and initiator flows (M/I) was constant at 12, three different regimes were observed by changing the reaction pressure. Without wishing to be bound by theory, it was postulated that these regimes were surface reaction dominated, transition region, and gas-phase dominated regimes. In contrast, as shown in FIG. 11B, when M/I was decreased from 12 to 3 by increasing the initiator partial pressure and keeping the monomer partial pressure constant at 277 mTorr, four distinct regimes were observed, attributed to surface reaction, transition, gas-phase dominated, and termination dominated regimes. Table 1 includes the reaction conditions for each data point in FIGS. 11A and 11B.

TABLE 1
The reaction conditions for the data points in FIGS. 11A and 11B

| | a. Constant M/I = 12 | | | b. Changing M/I | | | |
|---|---|---|---|---|---|---|---|
| Preactor | Initiator | HFPO | Argon | Initiator | HFPO | Argon | |
| (mTorr) | (sccm) | (sccm) | (sccm) | (sccm) | (sccm) | (sccm) | M/I |
| 100 | 1 | 12 | 0 | — | — | — | — |
| 200 | 1 | 12 | 0 | — | — | — | — |
| 300 | 1 | 12 | 0 | 1 | 12 | 0 | 12 |
| 400 | 1 | 12 | 0 | 1 | 9 | 3 | 9 |
| 500 | 1 | 12 | 0 | 1 | 7.2 | 4.8 | 7.2 |
| 600 | 1 | 12 | 0 | 1 | 6 | 6 | 6 |
| 700 | 1 | 12 | 0 | 1 | 5.14 | 6.86 | 5.14 |
| 800 | 1 | 12 | 0 | 1 | 4.5 | 7.5 | 4.5 |
| 900 | 1 | 12 | 0 | 1 | 4 | 8 | 4 |
| 1000 | 1 | 12 | 0 | 1 | 3.6 | 8.4 | 3.6 |
| 1100 | 1 | 12 | 0 | 1 | 3.27 | 8.73 | 3.27 |
| 1200 | 1 | 12 | 0 | 1 | 3 | 9 | 3 |

According to FIG. 11B, at pressures lower than 600 mTorr, the reaction rate changed linearly. However, the slope increased at higher pressures. This phenomenon can be explained by studying the dependence free radical polymerization rate to monomer and initiator concentrations. For this reason, a rate mechanism was proposed that included four initiations, two propagation, and four termination mechanisms to capture the reactions occurring in different conditions of the iCVD process. Table 2 shows the steps of free radical polymerization based on the proposed mechanisms.

TABLE 1
Postulated reactions occurring during deposition of PTFE

| Step | Reaction | Reaction |
|---|---|---|
| Dissociation of Initiator | 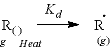 | Thermal hemolysis of initiator |
| Adsorption | 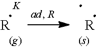 | Adsorption of primary radical |
| | 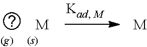 | Adsorption of monomer |
| Initiation | 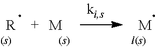 | Initiation on the surface |
| | 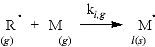 | Initiation due to collision in the gas phase |
| | 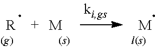 | Initiation due to impingement of primary radicals on the surface |

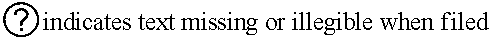

To decouple the effect of different mechanisms participating in the deposition rate, we first defined a balance on fraction sites occupied by each mechanism, as follows:

fᵥφ+f_{Rs}φ+f_{Rg}φ+f_{Ms}φ+f_{Mg}φ+fₜφ=φ (Equation 3)

where, φ is the total number of reactive surface sites available during the deposition. Here, the fractions are defined as the following:
fᵥ: Fraction of vacant sites on the surface
f_{Rs}: Fraction of sites occupied with adsorbed monomers reacting with adsorbed primary radicals
f_{Rg}: Fraction of sites occupied with monomer molecules reacting with primary radicals in the gas phase
f_{Ms}: Fraction of sites occupied with adsorbed monomer reacting with active chains on the surface
f_{Mg}: Fraction of sites occupied with adsorbed monomers on the surface reacting with the activated monomers in the gas phase
fₜ: Fraction of sites occupied with activated chains on the surface being terminated where
fₜ=f_{t,1}+f_{t,2}+f_{t,3}

Variables f_{Rs} and f_{Ms} are dependent on the partial pressure of monomer and initiator adsorbed on the surface. Therefore, we can define the adsorption rate as:

$${r}_{ad , {R}^{•}} = {k}_{ad , {R}^{•}} ( {f}_{v} {P}_{{R}^{•}} - \frac{{f}_{R s}}{{K}_{ad , {R}^{•}}} ) \qquad ( Equation 4 )$$

Since iCVD can be assumed to be an adsorption-limited process, the above equation can be simplified to:

$$\frac{{r}_{ad , {R}^{•}}}{{k}_{ad}} \approx 0 ⇒ {f}_{R s} = {f}_{v} {K}_{ad , {R}^{•}} {P}_{{R}^{•}} \qquad ( Equation 5 )$$

Similarly, to find f_{Ms}, the rate of adsorption for the monomer can be defined as:

$${r}_{ad , M} = {k}_{ad , M} ( {f}_{v} {P}_{M} - \frac{{f}_{M s}}{{K}_{ad , M}} ) \qquad ( Equation 6 )$$

By assuming an adsorption-limited condition:

$$\frac{{r}_{ad , M}}{{k}_{ad}} \approx 0 ⇒ {f}_{M s} = {f}_{v} {K}_{ad , M} {P}_{M} \qquad ( Equation 7 )$$

Variables fₜ, f_{Mg}, and f_{Rg} need to be calculated experimentally. The propagation stage includes two different mechanisms, a and b. The mechanism “a” shows the surface reaction between adsorbed monomer, Ms, and active chains, M₍ₛ₎^{•}, on the surface. Accordingly, the rate equation can be written as:

R_{p,a}=f_{Ms}k_{p,a}[M₍ₛ₎^{•}] (Equation 8)

Also, the second proposed mechanism for the propagation mechanism, mainly occurring at high pressures (P >800 mTorr), is the reaction between an active monomer site on the surface, Ms•, and a monomer molecule in the gas phase. The reaction rate in this pathway can be defined using the Eley-Rideal mechanism:

R_{p,b}=f_{Mg}k_{p,b}[M₍ₛ₎^{•}]P_{M} (Equation 9)

In addition, there are three terminations reactions—primary radical and activated chain termination mechanisms—competing with the propagation reaction. Depending on the M/I ratio, the significance of the termination reactions in the overall propagation rate changes. The termination reaction rate mechanisms can be written as:

R_{t,1}=f_{t,1}k_{t,1}[M₍ₛ₎^{•}]² (Equation 10)

R_{t,2}=f_{Rs}k_{t,2}[M₍ₛ₎^{•}] (Equation 11)

R_{t,3}=f_{t,3}k_{t,3}[M₍ₛ₎^{•}]P_{M}_{^{•}} (Equation 12)

Therefore, the overall deposition rate, Rp,overall, can be written as the following:

$${R}_{d , overal} = \frac{( {f}_{M s} {k}_{p , a} + {f}_{Mg} {k}_{p , b} {P}_{M} ) [ {M}_{( s )}^{•} ]}{1 + [ {M}_{( s )}^{•} ] ( {f}_{t , 1} {k}_{t , 1} [ {M}_{( s )}^{•} ] + {f}_{R s} {k}_{t , 2} + {f}_{t , 3} {k}_{t , 3} {{P}_{M}}^{•} )} \qquad ( Equation 13 )$$

where [M₍ₛ₎^{•}] is the total concentration of the number of active sites.

According to Equation 13, the overall propagation rate is the competition between termination and propagation rates. For example, if the termination terms become negligible, the denominator in Equation 13 goes toward unity. In the disclosed process, this condition happens at low reaction pressures (FIG. 11A). Thus, the termination rate was negligible. Also, due to low pressure, the low partial pressure of monomer and initiator reduced the number of nucleation sites and impingement on the surface. Thus, the reaction mainly happens on the surface (f_{Ms}>>f_{Mg}). As a result, the overall reaction rate can be simplified to:

R_{d,overal}=f_{Ms}k_{p,a}[M₍ₛ₎^{•}] (Equation 14)

However, in pressures higher than 600 mTorr, the activated chains on the surface start reacting with monomer molecules in the gas phase due to higher impingement of monomer molecules with the surface at higher pressures. Therefore, the reaction rate increases. In this state, at constant M/I, the termination rates are still negligible. Hence, the overall reaction rate can be defined by the following equation:

R_{d,overal}=(f_{Ms}l_{p,a}+f_{Mg}k_{p,b}P_{M})[M₍ₛ₎^{•}] (Equation 15)

FIG. 11B shows the reaction rate where the monomer partial pressure was kept constant at a low limit for all pressures. Accordingly, the partial pressure of the initiator was increased to observe all rate-transition stages. As shown in FIG. 11B, at low pressures, when the initiator partial pressure was low (high M/I), the overall reaction mechanism followed a pathway similar to that of FIG. 11A. Also, the reaction rate followed Equation 15 at pressures larger than 700 mTorr and intermediate monomer to initiator ratio. However, at monomer to initiator ratios smaller than 4, the termination reactions became dominant, reducing the overall rate of deposition. At this condition, the denominator terms in Equation 13 are not negligible.

### Example 9. Gas-Phase and Surface Reaction Measurements

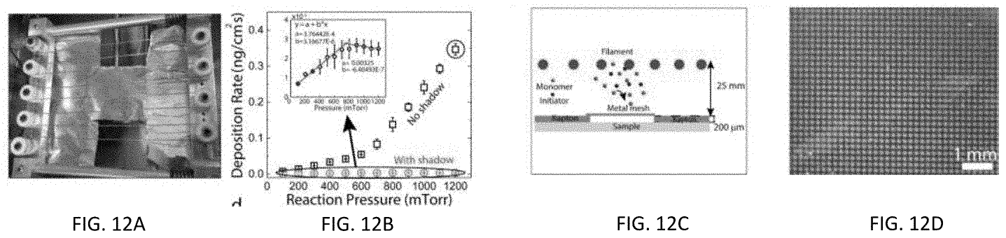

To differentiate the gas-phase reaction from the surface reaction regime (conventional iCVD), an aluminum foil shadow mask was used between the filament and the QCM crystal (FIG. 12A) and deposition rate recorded as a function of the total pressure. As shown in FIG. 12B, at 100 mTorr, the reaction rate with and without using a mask was in the same range. However, when a mask was used (the inset graph) between the filament and sample surface, the rate of change of reaction rate with pressure adopted two different slopes. The first region located at pressures below 800 mTorr, where the rate of reaction changed linearly with an average slope of 3.2e-6. At pressures above 800 mTorr, nonetheless, the rate of reaction on the surface reduced with a slope of −6.4e-7. Without wishing to be bound by theory, it was postulated that, at this condition, most of the monomer molecules reacted in the gas-phase, causing the reaction rate on the surface to decrease. To show the gas-phase reaction visually, a metal mesh was placed about 200 μm above the sample (schematic shown in FIG. 12C), between the filament and the Si wafer sample, and PTFE deposition performed at high pressure, 1200 mTorr. According to FIG. 12D, after removing the mask, the deposition patterns made on the surface of the planar sample were observed, indicative of gas-phase reactions occurring at high deposition pressures.

To confirm the grafting of PPFDA onto the PTFE domain, model QCM substrates were prepared representing the surface of the membranes. To do so, thin films of PTFE were deposited on QCM crystals. To make the surface of these QCM crystals comparable with that of the membrane, the same iCVD condition used in Steps (i) and (ii) were adopted. To examine the grafting of PFDA to the substrate, first, two distinct PTFE surfaces were created, namely terminated and unterminated; then these surfaces were exposed to PFDA monomer at similar vapor pressure as in Step (iii). The terminated samples refer to the crystal surfaces for which the growth of the PTFE chains was terminated with the primary radicals. To terminate the growing chains, before pumping down the chamber, the flow of monomer was stopped at the end of the PTFE iCVD cycle and the initiator allowed to flow for five minutes. In contrast, the unterminated samples refer to the PTFE-coated crystals that did not go through the termination step, i.e., at the end of the reaction cycle, the chemical flows were stopped, and the chamber was evacuated immediately.

### Example 10. Determination of CF₃/CF2 Ratio for Terminated and Unterminated PTFE

To calculate the CF3/CF2 ratio using angle-resolved XPS measurements, two different samples were prepared, referred to as terminated and unterminated. The procedure for making these surfaces was as follows:

Terminated surface: (I) PTFE deposition on QCM crystal at 100 mTorr for 10 min (Ts=15° C., M/I=12). (II) 5 min termination at 300 mTorr using initiator (1 sccm) at the presence of hot filament (˜350° C.), and (iii) Degassing in vacuum at substrate temperature 50° C. for 30 minutes.

Unterminated surface: (i) PTFE deposition on QCM crystal at 100 mTorr for 10 min (Ts=15° C., M/I=12), and (ii) Degassing in vacuum for about 3 minutes.

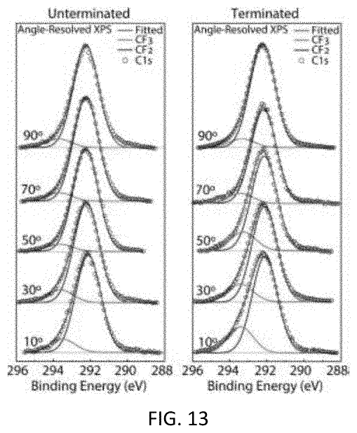

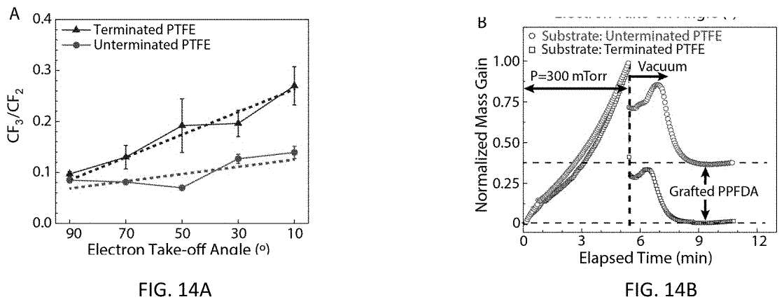

The model substrates were then characterized using angle-resolved X-ray photoelectron spectroscopy (AR-XPS). The CF3/CF2 ratio of terminated and unterminated PTFE samples was calculated using C1s core electron spectra acquired from the AR-XPS measurements. The electron take-off angle was changed from 90 (regular XPS measurements) to 10 degrees with an increment of 20 degrees. FIG. 13 and FIG. 14A illustrate the fitted C1s core electron spectra at different angles for terminated and unterminated surfaces. Table 3 shows the tabulated data with one standard deviation. For the terminated surfaces, the ratio of CF3 to CF2 significantly increased at low take-off angles, while no discernable change in the CF3 to CF2 ratio was measured for the unterminated samples. These results indicated that the terminal groups on the surface were dominated by the CF3 groups, suggesting that the growing PTFE chains were terminated by the initiator radicals. The calculated CF3 to CF2 ratio for each sample is provided in Table 3.

TABLE 3
The CF₃ to CF₂ ratios calculated using C1s core electron spectra
of PTFE samples at different electro takeoff angles

| | Unterminated PTFE | | | | Terminated PTFE | | | |
|---|---|---|---|---|---|---|---|---|
| | FWHM | CF₂ | CF₃ | | FWHM | CF₂ | | |
| | CF₃/CF₂ | area % | area % | CF₃/CF₂ | CF₂/CF₃ | area % | CF₃ area % | CF₃/CF₂ |
| 90 | 1.6/1.6 | 92.16 | 7.84 | 0.085 ± | 1.6/1.6 | 91.14 | 8.86 | 0.097 ± |
| | | | | 0.005 | | | | 0.005 |
| 70 | 1.6/1.6 | 92.5 | 7.5 | 0.081 ± | 1.6/1.6 | 88.45 | 11.55 | 0.130 ± |
| | | | | 0.004 | | | | 0.023 |
| 50 | 1.6/1.6 | 93.42 | 6.58 | 0.070 ± | 1.6/1.6 | 83.9 | 16.1 | 0.192 ± |
| | | | | 0.004 | | | | 0.053 |
| 30 | 1.6/1.6 | 88.61 | 11.39 | 0.127 ± | 1.6/1.6 | 83.47 | 16.53 | 0.196 ± |
| | | | | 0.009 | | | | 0.026 |
| 10 | 1.6/1.6 | 87.78 | 12.22 | 0.139 ± | 1.6/1.6 | 78.67 | 21.33 | 0.27 ± |
| | | | | 0.012 | | | | 0.03 |

### Example 11. QCM Measurements on Terminated and Unterminated Surfaces

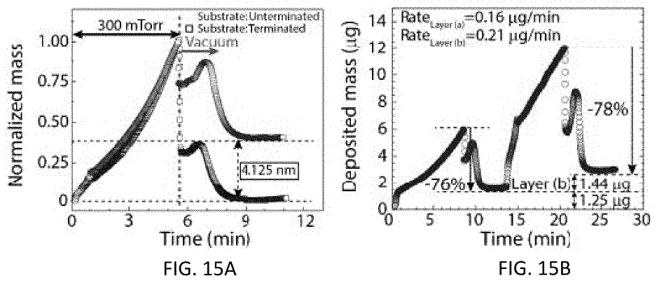

To investigate if PFDA can be grafted to PTFE structures, terminated and unterminated PTFE coated quartz crystal microbalance (QCM) surfaces were exposed to PFDA vapor. FIG. 15A shows the normalized mass accumulation on the QCM crystal when a terminated and unterminated PTFE surfaces were exposed to PFDA monomer vapor (0.5 sccm) and argon (5 sccm) at 300 mTorr in the absence of initiator and hot filament. The exposure for each surface was done right after the substrate preparation steps described in Example 9. The accumulative mass on the QCM was recorded after starting the experiment. As shown in FIG. 15A, the reaction was continued for 6 minutes, after which the PFDA monomer was stopped, and the pressure of the reactor was suddenly reduced to the base pressure (˜20 mTorr). Afterward, the substrates were degassed in a vacuum at 50° C. for about 30 minutes. FIG. 14B shows the normalized mass gain on the QCM crystals after exposing the terminated and unterminated surfaces to PFDA vapor, followed by evacuating the chamber. For the terminated surface, the total mass gain after pumping the chamber was zero (i.e., all the adsorbed PFDA molecules left the surface after reducing the pressure, as the adsorption was physical. Without wishing to be bound by theory, it is believed that when the surface of PTFE was terminated, the CF2 radicals on the surface were quenched with the initiator. In contrast, for the unterminated sample, a residual mass gain on the substrate was observed. Specifically, it was found that when the surface of PTFE was not terminated, the PTFE growing chains on the surface activated adsorbed PFDA monomers, and polymerization of PFDA initiated (making a grafted film). Without wishing to be bound by theory, it is believed that the unterminated radicals of the deposited PTFE chains enable the surface-initiated radical polymerization of PFDA, leading to the growth and deposition of PPFDA on the PTFE surface.

To confirm these results, we repeated the experiment on the unterminated surface for a longer time, in two consecutive steps, shown in FIG. 15B. Similar to the last experiment, the surface of the unterminated PTFE surface was exposed to the vapor of PFDA monomer, and argon (0.5 sccm PFDA, and 5 sccm Argon) in 300 mTorr and the accumulative mass on the QCM crystal was recorded. The reaction was continued for 8 minutes after which the PFDA monomer was stopped, and the pressure of the reactor was suddenly decreased to the base pressure (20 mTorr). The total rate of mass accumulation was 0.78 μg/min from which 0.15 μg/min was calculated to be the rate of mass accumulation on the unterminated PTFE surface. After reaching a steady state in three minutes, the surface was again exposed to PFDA vapor and argon. Likewise, the same rate of adsorption and reaction on the surface was observed. The mass did not leave the surface after heating it at 50° C. overnight in the vacuum, indicating that PFDA was grafted to the surface.

### Example 12. Spectroscopic Studies of the Membranes

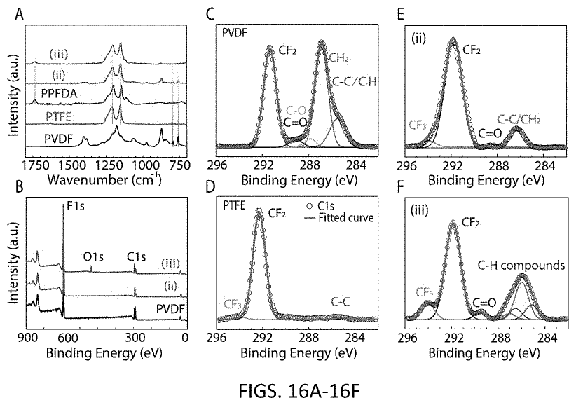

To understand the chemistry of the deposited materials, XPS and attenuated total reflectance Fourier transform infrared (ATR FTIR) spectroscopy were utilized. FIG. 16A presents the FTIR spectra for the substrate (PVDF), control deposited materials, and the coated substrates at each step during the nanofabrication process. As shown, for the omniphobic membrane, labeled (iii), the characteristic peaks of PVDF, located at 766 (CF2 bending) and 795 (CH2 rocking) cm-1, assigned to the a phase of PVDF, are masked by the spectra of the deposited layers. Furthermore, from the spectra of the omniphobic surface, a vibration at 1750 cm-1 can be identified; this stretching vibration was associated with the carbonyl groups of PPFDA. By comparing the spectra of the samples processed at Steps (ii) and (iii), it was noted that the peaks corresponding to the CF2 symmetric and asymmetric stretching vibration modes of PTFE, in the range of 1100-1200 cm-1, were the salient features in both spectra.

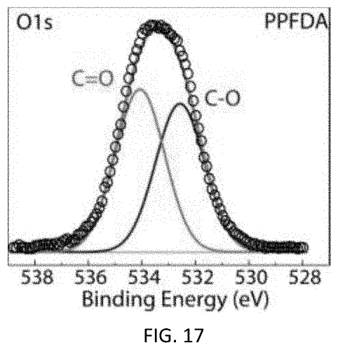

FIG. 16B presents the XPS survey spectra for the control and coated substrates. The sample coated with PPFDA, (iii), had a distinct peak at ˜530 eV, corresponding to O1s in PPFDA molecules; the estimated C/O ratio was 6.76, which is close to the theoretical stoichiometry ratio of C/O in the PFDA molecule; the O1s spectrum, shown in FIG. 17, confirmed the presence of two oxygen groups of methacrylate monomer with a one-to-one ratio. According to the theoretical stoichiometry of PPFDA, the ratio of C═O and C—O should be unity. Likewise, peak devolution analysis showed a ratio close to unity, ˜1.06.

FIG. 16C shows the high-resolution C 1 s spectrum of the control PVDF supports. The peaks at 285.3, 286.8, 287.8, 289, and 291.5 eV are assigned to C—C/C—H, CH2, C—O, C═O, and CF2 species, respectively. Here, the C1s of a PTFE film deposited on a silicon wafer substrate, shown in FIG. 16D, was used as a control for assigning the peaks. the C1s in the PTFE control spectrum was deconvoluted into three peaks, centered at 294, 292, and 285 eV. These binding energies were attributed to CF3, CF2, and C—C species, respectively. the CF3 peak, which appeared in the C1s spectrum of the PTFE sample was attributed to the initiator molecules; it was expected that the end groups in the polymer chains were capped with CF3. The C1s spectrum of a PVDF substrate coated with a thin film of PTFE is also shown in FIG. 16E. The two additional peaks are centered at 289 eV, and 285.8 eV ascribed to C═O (adventitious carbon) and C—H species of the substrate, PVDF, respectively. FIG. 16F displays the high-resolution C1s spectra of the omniphobic surface—the PVDF substrate coated with two PTFE layers followed by the deposition of PPFDA. As shown, seven peaks centered at 294, 292, 289.3, 287.1, 287, 286, and 285.1 eV were identified. These peaks were assigned to —CF3, —CF2-, —C═O, —CH2-CH2-CF2, —O—CH2-CH2, —CH—CO—, —C—CH2-C—, respectively.

### Example 13. Effect of Pressure on Morphology of PTFE Deposition

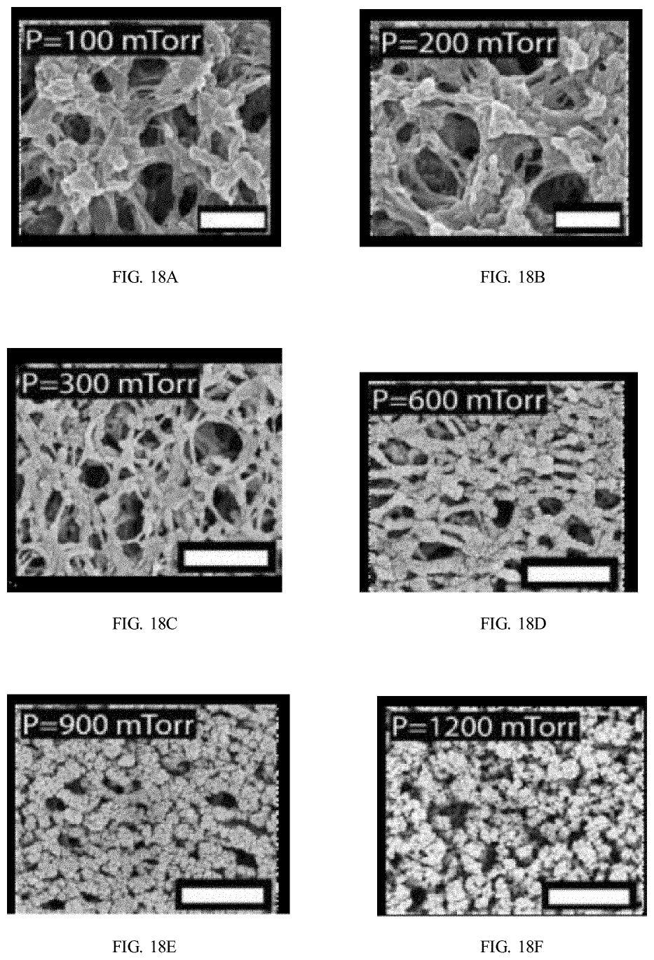

The effect of pressure on the PTFE deposition was evaluated. As illustrated in FIGS. 18A-18F, for pressures ranging from 100 mTorr to 1200 mTorr, the morphology of deposited PTFE significantly changed. Specifically, as the pressure increased, the morphology of PTFE moved from a smooth lateral deposition toward a vertically grown reentrant structure.

### Example 14. Effect of Deposition Pressure on the PTFE Crystallinity

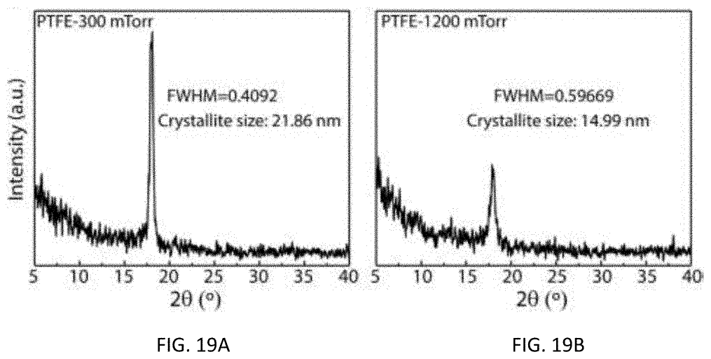

After observing that the PTFE morphology significantly changed with deposition pressure, PTFE was deposited on the planar surfaces (Si wafer) to study the crystallinity of deposited film. FIGS. 19A and 19B show the X-ray diffraction (XRD) patterns of the PTFE films deposited on planar surfaces at 300 mTorr, and 1200 mTorr, respectively. While the location of the PTFE characteristic peak was the same for both samples, the different full width at half maximums (FWHMs) is an indication of the change in crystallite sizes. For this reason, curve fitting was performed to find the FWHM of the picks. The size of the PTFE crystallites was calculated using the Scherrer equation (Equation 16), defined as

$$τ = \frac{K λ}{β cos ( θ )} \qquad ( Equation 16 )$$

where τ is the mean size of the ordered (crystalline) domains; K is a dimensionless shape factor, with a value close to unity (0.9-1); λ is the x-ray wavelength (1.5418 Å); β is the peak FWHM in radian; and θ is the Bragg angle in radian. The calculations indicated that the crystallite size of PTFE decreased by 31% when the iCVD deposition pressure increased from 300 mTorr to 1200 mTorr.

### Example 15. Membranes for Membrane Distillation

Membranes were prepared for application in membrane distillation using the same processing parameters in Examples 1A, 1B, and 1C, but with varying reaction pressure 1B. Here, two distinct surfaces (reentrant structures) were prepared using 900 and 1200 mTorr total pressure in Example 1C, and labeled PTFE900-PPFDA and PTFE1200-PPFDA, respectively. The composition of the two membranes is provided in Table 4.

TABLE 4
The layer-by-layer composition of fabricated omniphobic surfaces

| | | Pore | | |
|---|---|---|---|---|
| | | Narrowing | Reentrant | Top |
| Sample | Substrate | Layer | Layer | Layer |
| PTFE900-PPFDA | PVDF | PTFE, | PTFE, | PPFDA, |
| | | 100 mTorr | 900 mTorr | 300 mTorr |
| PTFE1200-PPFDA | PVDF | PTFE, | PTFE, | PPFDA, |
| | | 100 mTorr | 1200 mTorr | 300 mTorr |

### Example 16. Effect of Surface Morphology on Wetting Properties

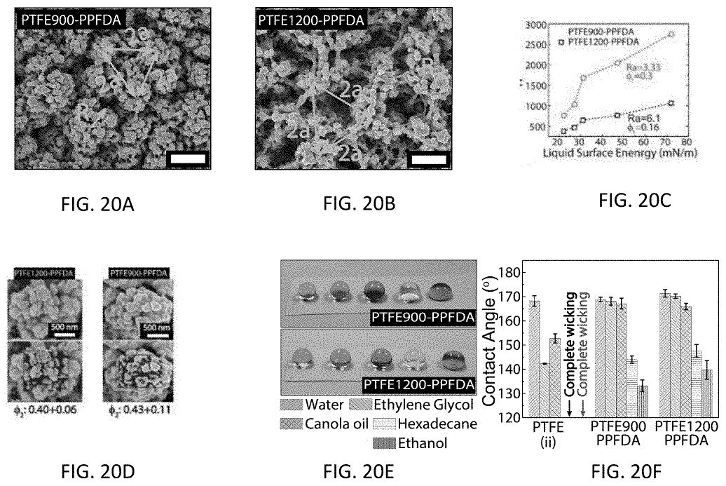

Top-down SEM images of the fabricated surfaces were analyzed to calculate the robustness of their omniphobic properties of PTFE900-PPFDA and PTFE1200-PPFDA membranes, FIGS. 20A and 20B, respectively. The SEM images are annotated with R and 2a to highlight the differences in the surface topography. Briefly, from the top-down SEM images, as shown in FIGS. 20A and 20B, the averaged radius of columnar structures and the center-to-center distance between these structures as R and 2a, respectively, was defined. The interactions between different liquids and the assembled reentrant structure were studied using two parameters: the spacing ratio (Ra=[(R+a)/R]2) and the robustness factor (H*). The Ra parameter directly influences the fraction of the surface in contact with the liquid. This parameter changes the apparent contact angle (θ*) of liquid on the surface. The second parameter, H*, determines the stability of the Cassie-Baxter state for different liquids in contact with the reentrant structure. This factor is a function of the liquid properties, equilibrium contact angle, and surface chemistry and morphology. A high value of θ* indicates that proper spacing exists between the reentrant structures and that the chemical modification is effective.

It was found that by adjusting the total pressure in Example 1C, surfaces with distinct topographies could be created. This change in topography directly influences the surface parameters: Ra and H*. As a result, surfaces with different wettability can be obtained. The averaged “Ra” values for PTFE1200-PPFDA and PTFE900-PPFDA were calculated to be 6.13±0.1 and 3.33±0.13, respectively. To calculate the average numbers, more than 100 measurements were performed using image analysis (ImageJ) over an area of 10000 μm2. FIG. 20C shows the calculated robustness factor for liquids with different surface energies in contact with the mentioned omniphobic surfaces. Although both surfaces show high robustness values for all tested liquids, the robustness factor of PTFE900-PPFDA sample is higher than that of PTFE1200-PPFDA because the structures are more packed (i.e., the interspacing parameter is smaller) on the membrane surface. That means more pressure is needed to induce liquid intrusion into the PTFE900-PPFDA samples. However, the PTFE1200-PPFDA samples showed higher apparent contact angles for all tested liquids. This observation can be explained using the Ra, which directly affects ϕs,1, as a result of higher spacing between reentrant structures.

In addition to roughness factor due to spacing between reentrant structures, the second roughness level, hierarchical morphologies existing on the PTFE reentrant structures, needed to be considered. For this reason, the fraction of solid on individual microstructures of the surface in contact with liquid, ϕs,2, was calculated using image analysis (ImageJ). As shown in FIG. 20D, the projected area of the hierarchical morphologies on the surface of reentrant structures (grey area in the inset, As) was estimated and divided by the total area used in the image analysis (blue & grey area, At). Accordingly, ϕs,2=As/At was calculated. The total roughness of the omniphobic surfaces was calculated using the following equation (Equation 17):

ϕₛ=ϕ_{1,s}×ϕ_{2,s}=ϕ_{s,2}[R/(R+a)]² (Equation 17)

The values for the Ra, as well as the H* parameter of the PTFE1200-PPFDA and PTFE 900-PPFDA surfaces when they were brought into contact with different liquids are provided in Table 5.

TABLE 5
Calculated parameters for two different omniphobic surfaces

| | | | | | γ, | Liquid | | Contact | |
|---|---|---|---|---|---|---|---|---|---|
| | R, Avg. | 2a, Avg. | ϕₛ | | liquid | Density | LCap | angle | H*, |
| | (nm) | (nm) | (ϕs, 1*ϕs, 2) | Ra | (mN/m) | (kg/m³) | (mm) | (°) | Avg. |
| PTFE1200- | 895 ± 145.8 | 2639 ± 518 | 0.163*0.4 | 6.13 ± 0.1 | 22 | 769 | 1.7 | 140 | 378 |
| PPFDA | 895 ± 145.8 | 2639 ± 518 | 0.163*0.4 | 6.13 ± 0.1 | 27 | 770 | 1.8 | 147 | 469 |
| | 895 ± 145.8 | 2639 ± 518 | 0.163*0.4 | 6.13 ± 0.1 | 31 | 913 | 1.8 | 166 | 648 |
| | 895 ± 145.8 | 2639 ± 518 | 0.163*0.4 | 6.13 ± 0.1 | 47 | 1110 | 2.0 | 169 | 768 |
| | 895 ± 145.8 | 2639 ± 518 | 0.163*0.4 | 6.13 ± 0.1 | 72 | 1000 | 2.7 | 172 | 1065 |
| PTFE900- | 965 ± 269 | 1590 ± 374 | 0.3*0.43 | 3.33 ± 0.16 | 22 | 769 | 1.7 | 132 | 760 |
| PPFDA | 965 ± 269 | 1590 ± 374 | 0.3*0.43 | 3.33 ± 0.16 | 27 | 770 | 1.8 | 143 | 1034 |
| | 965 ± 269 | 1590 ± 374 | 0.3*0.43 | 3.33 ± 0.16 | 31 | 913 | 1.8 | 165 | 1680 |
| | 965 ± 269 | 1590 ± 374 | 0.3*0.43 | 3.33 ± 0.16 | 47 | 1110 | 2.0 | 168 | 2042 |
| | 965 ± 269 | 1590 ± 374 | 0.3*0.43 | 3.33 ± 0.16 | 72 | 1000 | 2.7 | 169 | 2744 |

To evaluate the wettability of the fabricated omniphobic surfaces, we chose five different liquids: deionized water (72 mN m-1), ethylene glycol (47 mN m-1), canola oil (31 mN m-1), hexadecane (26 mN m-1), and ethanol (22 mN/m); photo of liquids in contact with the membranes is shown in FIG. 20E. The droplets of deionized water, ethylene glycol, canola oil, hexadecane, and ethanol formed contact angles between 80 and 175 degrees on the fabricated omniphobic porous surfaces.

FIG. 20F show the θ* for water (72 mN m-1), ethylene glycol (47 mN m-1), and canola oil (31 mN m-1). The values for the apparent contact angles were more than 160o on both PTFE900-PPFDA and PTFE1200-PPFDA surfaces. The values for θ* on the PTFE1200-PPFDA were in general larger than those of PPTFE900-PPFDA; this was attributed to a larger interspacing parameter of PTFE1200-PPFDA. The θ* value for the samples that did not go through Step (iii) of the fabrication process (labeled PTFE (ii) in FIG. 20F) was measured to distinguish the effect of surface chemistry and the morphological properties. As shown in FIG. 20F, PTFE (ii) retained droplets of water, ethylene glycol, and canola oil with a θ* of more than 150o, while hexadecane and ethanol wicked through the sample. The reported value for θ* on the control PVDF support was 108o±4.3. All other liquids wicked through the PVDF support.

The resistance to wetting of the omniphobic porous surfaces may be described in terms of Weber number. The Weber number (We) is a dimensionless number in fluid mechanics that is useful in analyzing fluid flows where there is an interface between two different fluids. The Weber number may be written as:

$$We = \frac{Drag Force}{Cohesion Force} = ( \frac{8}{{C}_{D}} ) \frac{( \frac{ρ {v}^{2}}{3} {C}_{D} π \frac{{l}^{2}}{4} )}{( π l σ )} = \frac{ρ {v}^{2} l}{σ}$$

where
C_{D} is the drag coefficient of the body cross-section;
p is the density of the fluid (kg/m3);
u is its velocity (m/s);
l is its characteristic length, typically the droplet diameter (m); and
σ is the surface tension (N/m).

The modified Weber number,

$${We}^{*} = \frac{We}{12}$$

equals the ratio of the kinetic energy on impact to the surface energy,

$${We}^{*} = \frac{{E}_{kin}}{{E}_{surf}} ,$$

where

$${E}_{kin} = \frac{π ρ {l}^{3} {v}^{2}}{12}$$

and

E_{surf}=πl²σ.

In some embodiments, the omniphobic porous surface as disclosed herein is resistant against wetting by impacting liquids with Weber numbers between 100 and 500. In some embodiments, the impacting liquid is deionized water, ethylene glycol, canola oil, hexadecane, or ethanol.

### Example 17. Liquid Droplet Impacts on Omniphobic Surfaces

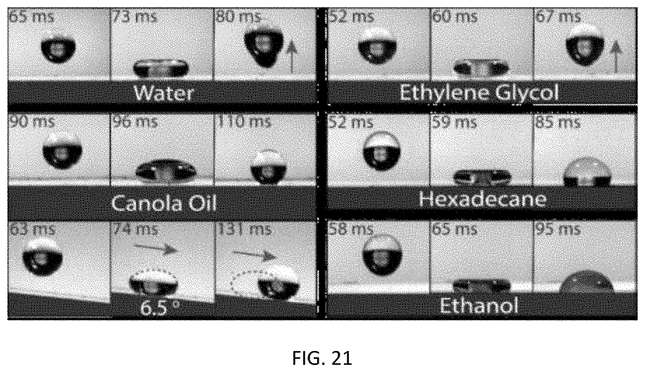

To further analyze the robustness of the omniphobic surfaces, large (1.5-2.0 mm in diameter) liquid droplets of various liquids were allowed to impact the PTFE1200-PPFDA omniphobic membrane surface of Example 16 with a velocity of about 2 m/s. FIG. 21 shows high-speed camera images (5000 frames per second) taken before and after the droplets impacted the omniphobic membrane surfaces. The rolling contact angle (RCA) for water and ethylene glycol was almost zero, while it was 6.5o for canola oil. For water and ethylene glycol, the kinetic energies of the incident droplets transform into vibrational energy, allowing the droplet to rebound several times before it went through dampening oscillations and finally rested on the surface in a stable Cassie-Baxter state. Interestingly, the suspended membranes retained their omniphobicity even after many droplets (>1000) impinged on the surface from 1.5-2 mm distance with a velocity of 2-2.3 m/s.

### Example 18. Direct Contact Membrane Distillation (DCMD)

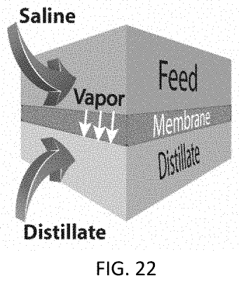

Maintaining the omniphobicity of porous membranes in thermal processes such as direct contact membrane distillation (DCMD) is challenging. In DCMD, as shown schematically in FIG. 22, the porous membrane acts as a physical barrier between a feed (hot saline water) and a cold distillate stream, allowing only for the water vapor to pass through. In this process, the average temperature of the membrane remains lower than that of the hot saline solution; consequently, the water vapor within the porous domain is subjected to pore condensation, a possible mechanism that can lead to the performance deterioration. To evaluate the performance of the disclosed membranes, DCMD tests were performed using a custom-made setup for an extended period.

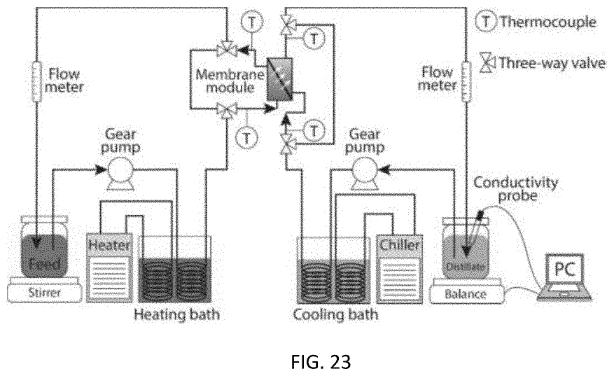

FIG. 23 shows the schematic of the DCMD setup utilized. The membrane was placed into a custom-built cell with channel dimensions of 77 mm in length, 26 mm in width, and 3 mm in depth. The effective membrane area exposed to feed and distillate streams was about 19 cm2. Two plastic spacers (Nylon, McMaster-Carr) were used in the feed and permeate channels to support the membrane in the cell. The temperatures of the feed and permeate streams at the entrance of the membrane module were measured to be 68° C. and 18° C., respectively, using inline thermocouples (type K, Omega Engineering). The water vapor flux across the membrane was determined by the gravimetric method. The distillate conductivity was continuously measured using a conductivity probe (Oakton 2700, Cole Parmer) to calculate the NaCl concentration in the permeate stream. The control feed solution was composed of 0.6 m sodium chloride in DI water. When needed, sodium dodecyl sulfate was added to the feed solution to reduce the surface tension of the feed and challenge the membranes.

As a general procedure, the DCMD test began by examining the performance of the control PVDF membrane (the supporting substrate), in the desalination of a feed solution containing 35,000 mg/L NaCl and a variable amount of sodium dodecyl sulfate (SDS) was added incrementally up to 0.4 mm. The feed concentration was adjusted so that every 60 min the SDS concentration increased by 0.1 mm.

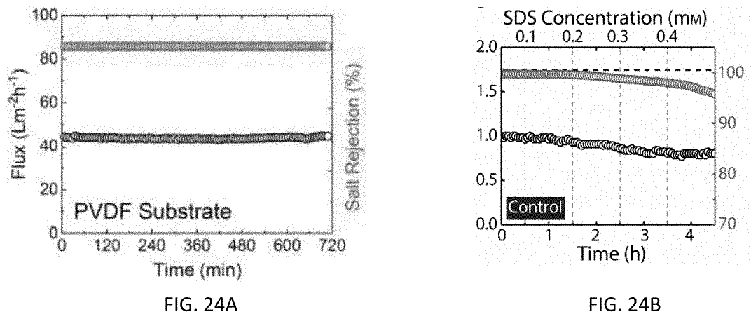

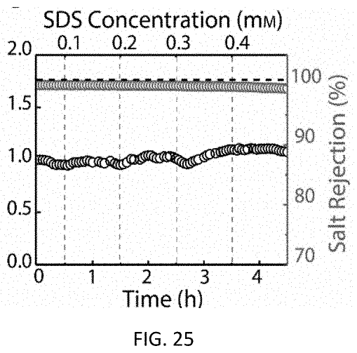

FIG. 24A shows the DCMD results, in the absence of SDS, of the pristine control PVDF membrane used as a substrate for the omniphobic membranes. The performance of the control PVDF membrane in the presence of SDS is presented in FIG. 24B. As shown, after the addition of 0.1 mm SDS to the feed solution, the salt rejection for the control membrane declines. The loss of performance was attributed to the wicking of the feed solution into the control substrate. The surface tension for the feed solution containing 0.1 mm SDS is estimated to be ˜54 mN m-1. In contrast, FIG. 25 indicates that the salt rejection values for the omniphobic membranes remained stable until the SDS concentration reached 0.3 mm; the equivalent surface tension for this solution was ˜43 mN m-1. When the SDS concentration increased to 0.4 mm, a decline in salt rejection was observed.

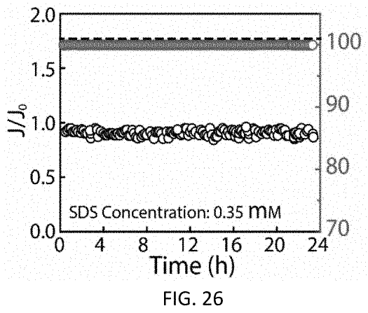

To evaluate the effect of feed surface tension on the wetting properties of the membrane, prolonged DCMD tests were performed on the omniphobic membranes using a saline feed solution composed of 0.25 and 0.35 mm SDS. The results are shown in FIG. 26. As shown, under these conditions, stable values for salt rejection above 99.5% were measured during the 24 hours of continuous operation.

### Example 19. Direct Contact Membrane Distillation (DCMD) of Waste Water

To further validate the omniphobic properties of the PTFE1200-PPFDA, bench-scale DCMD experiments were performed using a real desalination concentrate collected from a municipal waste water reuse facility in Arizona, USA. Municipal wastewater RO brine was obtained from a local water reuse facility in Arizona. Before reaching the RO unit, the feed water was treated using the primary and secondary biological treatment, ozonation, and microfiltration. Anti-scalants were also added before the RO unit to limit scaling. The feed water was received after a ˜85% recovery reverse osmosis unit and had a total dissolved solid of ˜6270 mg/L, dissolved organic carbon content of 65 mg/L, and a pH of 7.2. The RO brine was collected in clean polypropylene carboys and stored at 4° C. until use.

Bench-scale DCMD experiments with the RO brine were done using a membrane area of 20 cm2. A volume of 1 L was used in the feed reservoir, which was kept at 60° C. using glass coils immersed into a hot water bath (Equatherm, Curtin Matheson Scientific, Inc, Houston, Tex.). The distillate reservoir (2.5 L) was kept at 20° C. using a Polystat chiller (Cole-Parmer, Vernon Hills, Ill.) and placed on a digital scale connected to a computer for continuous weight measurement. A conductivity probe (Orian VERSA STAR, Thermo Fisher Scientific, Waltham, Mass.) was used to monitor the salinity of the condensate water. Gear pumps (Cole-Palmer, Vernon Hills, Ill.) connected to flowmeters were used to control the crossflow velocities of the feed and distillate sides to 0.26 and 0.22 m/s, respectively. Between each experiment, the DCMD system was thoroughly cleaned with DI water, sodium hydroxide (pH 11), 10% bleach, and finally rinsed with DI water.

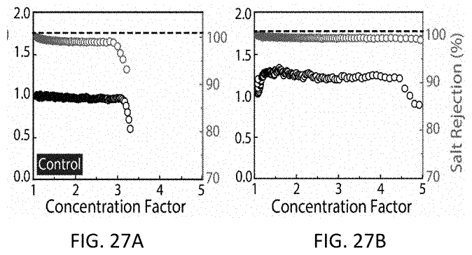

During the DCMD treatment of this brine, using the control PVDF membrane, a two-step wetting process was observed. As shown in FIG. 27A, an initial decline in salt rejection to 98.3% occurred at the onset of the experiment, which can be attributed to the complex mixture of organic compounds in the wastewater desalination concentrate. Then, upon reaching a concentration factor of ˜3, both salt rejection and distillate flux declined. However, the omniphobic PTFE1200-PPFDA membrane did not show the initial reduction in salt rejection, and the salt rejection remained at >99% for the duration of the experiment (FIG. 27B). Even upon the initial drop in the distillate flux-associated with the fouling of membrane by inorganic precipitates at a concentration factor of ˜4.5-salt rejection remained high. This observation demonstrated the exceptional wetting resistance of the disclosed omniphobic membrane, even in a complex brine solution.

What is claimed is:

1. A method for preparing a material having an omniphobic porous surface, the method comprising:
providing a porous substrate;
adjusting the average pore size and porosity of the porous substrate through controlled deposition of a first layer, wherein the controlled deposition comprises performing initiated chemical vapor deposition (iCVD) under reaction-limited conditions with a first monomer in the presence of a first initiator at a first substrate temperature, a first filament temperature, a first pressure, and a first monomer to initiator ratio, and wherein the first layer is a conformal coating;
assembling a reentrant structure on the porous substrate through controlled deposition of a second layer, wherein the controlled deposition comprises performing iCVD under diffusion-limited conditions with a second monomer in the presence of a second initiator at a second substrate temperature, a second filament temperature, a second pressure, and a second monomer to initiator ratio, and wherein the second layer is a non-conformal coating; and
engineering the surface energy of the reentrant structure, wherein the engineering comprises grafting a third layer onto the second layer, wherein the grafting comprises performing iCVD under reaction-limited conditions with a third monomer in the presence of a third initiator at a third substrate temperature, a third filament temperature, a third pressure, and a third monomer to initiator ratio, and wherein the third layer is a conformal coating.

2. The method of claim 1, wherein the porous substrate contains poly(vinylidene fluoride) (PVDF), polytetrafluoroethylene (Teflon), polyester, nylon, polycarbonate, cellulose acetate, polysulfone, ceramic, carbon nanotubes, titania nanowire, or a combination thereof.

3. The method of claim 1, wherein the first pressure is from about 100 mTorr to about 3 Torr.

4. The method of claim 1, wherein the first filament temperature is from about 200 to about 500° C.

5. The method of claim 1, wherein the first substrate temperature is from about 0 to about 100° C.

6. The method of claim 1, wherein the average pore size of the porous substrate ranges from about 100 nm to about 100 μm.

7. The method of claim 1, wherein the first monomer is one or more of hexafluoropropylene oxide, perfluorodecyl acrylate, glycidyl methacrylate, 1,3,5,7-tetravinyl-1,3,5,7-tetramethylcyclotetrasiloxane, 1,3,5-trimethyl-1,3,5-trivinyl cyclotrisiloxane, diethylaminoethyl methacrylate, 2,2,3,3-tetrafluoropropyl methacrylate, 2,2,3,3,4,4,5,5-Octafluoropentyl methacrylate, 2,2,3,3,4,4,4-heptafluorobutyl acrylate, 2,2,3,4,4,4-Hexafluorobutyl acrylate, 2,2,3,3-Tetrafluoropropyl methacrylate, 1H, 1H-perfluorooctyl methacrylate, 3,3,4,4,5,5,6,6,7,7,8,8,8-tridecafluorooctyl acrylate, 3,3,4,4,5,5,6,6,7,7,8,8,9,9,10,10,11,11,12,12,12-heneicosafluorododecyl acrylate, 2,2,2-trifluoroethyl acrylate, 1,1,1,3,3,3-hexafluoroisopropyl acrylate, 2,2,3,3,4,4,4-Heptafluorobutyl acrylate, and pentafluorophenyl methacrylate.

8. The method of claim 1, wherein the first layer contains one or more of polytetrafluoroethylene, poly(perfluorodecyl acrylate), poly(glycidyl methacrylate), poly(1,3,5,7-tetravinyl-1,3,5,7-tetramethylcyclotetrasiloxane), poly(1,3,5-trimethyl-1,3,5-trivinyl cyclotrisiloxane), poly(diethylaminoethyl methacrylate), poly(2,2,3,3-tetrafluoropropyl methacrylate), poly(2,2,3,3,4,4,5,5-octafluoropentyl methacrylate), poly(2,2,3,3,4,4,4-heptafluorobutyl acrylate), poly(2,2,3,4,4,4-hexafluorobutyl acrylate), poly(2,2,3,3-tetrafluoropropyl methacrylate), poly(1h,1h-perfluorooctyl methacrylate), poly(3,3,4,4,5,5,6,6,7,7,8,8,8-tridecafluorooctyl acrylate), poly(3,3,4,4,5,5,6,6,7,7,8,8,9,9,10,10,11,11,12,12,12-heneicosafluorododecyl acrylate), poly(2,2,2-trifluoroethyl acrylate), poly(1,1,1,3,3,3-hexafluoroisopropyl acrylate), poly(2,2,3,3,4,4,4-heptafluorobutyl acrylate), or poly(pentafluorophenyl methacrylate).

9. The method of claim 1, wherein the first initiator is a peroxide or a sulfonyl fluoride.

10. The method of claim 1, wherein the second monomer is one or more of hexafluoropropylene oxide, perfluorodecyl acrylate, glycidyl methacrylate, 1,3,5,7-tetravinyl-1,3,5,7-tetramethylcyclotetrasiloxane, 1,3,5-trimethyl-1,3,5-trivinyl cyclotrisiloxane, diethylaminoethyl methacrylate, 2,2,3,3-tetrafluoropropyl methacrylate, 2,2,3,3,4,4,5,5-Octafluoropentyl methacrylate, 2,2,3,3,4,4,4-heptafluorobutyl acrylate, 2,2,3,4,4,4-Hexafluorobutyl acrylate, 2,2,3,3-tetrafluoropropyl methacrylate, 1H,1H-perfluorooctyl methacrylate, 3,3,4,4,5,5,6,6,7,7,8,8,8-tridecafluorooctyl acrylate, 3,3,4,4,5,5,6,6,7,7,8,8,9,9,10,10,11,11,12,12,12-heneicosafluorododecyl acrylate, 2,2,2-trifluoroethyl acrylate, 1,1,1,3,3,3-hexafluoroisopropyl acrylate, 2,2,3,3,4,4,4-heptafluorobutyl acrylate, and pentafluorophenyl methacrylate.

11. The method of claim 1, wherein the second layer contains one or more of polytetrafluoroethylene, poly(perfluorodecyl acrylate), poly(glycidyl methacrylate), poly(1,3,5,7-tetravinyl-1,3,5,7-tetramethylcyclotetrasiloxane), poly(1,3,5-trimethyl-1,3,5-trivinyl cyclotrisiloxane), poly(diethylaminoethyl methacrylate), poly(2,2,3,3-tetrafluoropropyl methacrylate), poly(2,2,3,3,4,4,5,5-octafluoropentyl methacrylate), poly(2,2,3,3,4,4,4-heptafluorobutyl acrylate), poly(2,2,3,4,4,4-hexafluorobutyl acrylate), poly(2,2,3,3-tetrafluoropropyl methacrylate), poly(1h,1h-perfluorooctyl methacrylate), poly(3,3,4,4,5,5,6,6,7,7,8,8,8-tridecafluorooctyl acrylate), poly(3,3,4,4,5,5,6,6,7,7,8,8,9,9,10,10,11,11,12,12,12-heneicosafluorododecyl acrylate), poly(2,2,2-trifluoroethyl acrylate), poly(1,1,1,3,3,3-hexafluoroisopropyl acrylate), poly(2,2,3,3,4,4,4-heptafluorobutyl acrylate), or poly(pentafluorophenyl methacrylate).

12. The method of claim 1, wherein the second initiator is a peroxide or a sulfonyl fluoride.

13. The method of claim 1, wherein the third monomer is one or more of perfluorodecyl acrylate (PFDA), 1,3,5,7-tetravinyl-1,3,5,7-tetramethylcyclotetrasiloxane, 1,3,5-trimethyl-1,3,5-trivinyl cyclotrisiloxane, 2,2,3,3,4,4,4-heptafluorobutyl methacrylate, 3,3,4,4,5,5,6,6,7,7,8,8,8-tridecafluorooctyl methacrylate, 2,2,3,3-tetrafluoropropyl methacrylate, 2,2,3,3,4,4,5,5-octafluoropentyl methacrylate, 2,2,3,3,4,4,4-heptafluorobutyl acrylate, 2,2,3,4,4,4-hexafluorobutyl acrylate, and 2,2,3,3-tetrafluoropropyl methacrylate.

14. The method of claim 1, wherein the third layer contains one or more of poly(perfluorodecyl acrylate) (PPFDA), poly(1,3,5,7-tetravinyl-1,3,5,7-tetramethylcyclotetrasiloxane), poly(1,3,5-trimethyl-1,3,5-trivinyl cyclotrisiloxane), poly(2,2,3,3,4,4,4-heptafluorobutyl methacrylate), poly(3,3,4,4,5,5,6,6,7,7,8,8,8-tridecafluorooctyl methacrylate), poly(2,2,3,3-tetrafluoropropyl methacrylate), poly(2,2,3,3,4,4,5,5-octafluoropentyl methacrylate), poly(2,2,3,3,4,4,4-heptafluorobutyl acrylate), poly(2,2,3,4,4,4-hexafluorobutyl acrylate), or poly(2,2,3,3-tetrafluoropropyl methacrylate).

15. The method of claim 1, wherein the third initiator is a peroxide or a sulfonyl fluoride.

16. The method of claim 1, wherein the second pressure ranges from about 600 mTorr to about 3 Torr.

17. The method of claim 1, wherein the second filament temperature and the third filament temperature range from about 200° C. to about 500° C.

18. The method of claim 1, wherein the second substrate temperature and the third substrate temperature range from about 10° C. to about 50° C.

19. The method of claim 1, wherein the third pressure ranges from about 100 mTorr to about 3 Torr.

20. The method of claim 1, wherein the ratio of the first monomer to the first initiator, the ratio of the second monomer to the second initiator, and the ratio of the third monomer to the third initiator range from about 3 to about 12.
